(19) United States
(12) Patent Application Publication
(10) Pub. No.: US 2024/0405113 A1
(43) Pub. Date: Dec. 5, 2024

(54) SEMICONDUCTOR DEVICE

(71) Applicant: SAMSUNG ELECTRONICS CO., LTD., SUWON-SI (KR)

(72) Inventors: Yang XU, Suwon-si (KR); Gyeom KIM, Suwon-si (KR); Young Kwang KIM, Suwon-si (KR); Jin Bum KIM, Suwon-si (KR); Yoon Tae NAM, Suwon-si (KR); Kyung Bin CHUN, Suwon-si (KR); Ryong HA, Suwon-si (KR); Yoon HEO, Suwon-si (KR)

(21) Appl. No.: 18/537,916

(22) Filed: Dec. 13, 2023

(30) Foreign Application Priority Data
May 30, 2023 (KR) 10-2023-0069145

(51) Int. Cl. H01L 29/775; H01L 27/088; H01L 29/06; H01L 29/08; H01L 29/417; H01L 29/423; H01L 29/786

(52) U.S. Cl. CPC H01L 29/775; H01L 27/088; H01L 29/0673; H01L 29/0847; H01L 29/41775; H01L 29/42392; H01L 29/78696

(57) ABSTRACT

A semiconductor device includes a substrate. An active pattern extends in a first horizontal direction on the substrate. First to third nanosheets are sequentially spaced apart from each other in a vertical direction on the active pattern. A gate electrode extends in a second horizontal direction on the active pattern and surrounds the first to third nanosheets. A source/drain region includes a first layer disposed along side walls and a bottom surface of a source/drain trench and a second layer filling the source/drain trench. The second layer includes a first lower side wall facing a side wall of the first nanosheet and an opposite second lower side wall. A lower surface connects the first and second lower side walls and extends in the first horizontal direction. The first and second lower side walls of the second layer extend to have a constant slope in opposite directions to each other.

This application claims priority under 35 U.S.C. 119 to Korean Patent Application No. 10-2023-0069145, filed on May 30, 2023 in the Korean Intellectual Property Office, the disclosure of which is incorporated by reference in its entirety herein.

### 1. TECHNICAL FIELD

The present disclosure relates to a semiconductor device. In particular, the present disclosure relates to a semiconductor device including an MBCFET™ (Multi-Bridge Channel Field Effect Transistor).

### 2. DISCUSSION OF RELATED ART

A multi-gate transistor in which a silicon body having a fin or nanowire shape is formed on a substrate and a gate is formed on a surface of the silicon body is being developed as a scaling technology for increasing a density of an integrated circuit device.

Since such a multi-gate transistor utilizes a three-dimensional channel, scaling is relatively easily performed. Further, even if a gate length of the multi-gate transistor is not increased, the current control capability may be increased. Furthermore, a SCE (short channel effect) in which potential of a channel region is influenced by a drain voltage may be effectively suppressed.

### SUMMARY

Aspects of the present disclosure provide to provide a semiconductor device which prevents an occurrence of a short-circuit between a second layer, which is a filling layer of a source/drain region, and a gate electrode, and increases a region of the second layer which is the filling layer of the source/drain region to increase performance.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an embodiment of the present disclosure, a semiconductor device includes a substrate. An active pattern extends in a first horizontal direction on the substrate. First to third nanosheets are sequentially spaced apart from each other and stacked in a vertical direction on the active pattern. A gate electrode extends in a second horizontal direction crossing the first horizontal direction on the active pattern. The gate electrode surrounds each of the first to third nanosheets. A source/drain trench is positioned on at least one side of the gate electrode on the active pattern. A source/drain region includes a first layer disposed along side walls and a bottom surface of the source/drain trench, and a second layer disposed on the first layer. The second layer fills an inside of the source/drain trench. In a cross-section taken along the first horizontal direction, the second layer includes a first lower side wall facing a side wall of the first nanosheet, a second lower side wall opposite to the first lower side wall in the first horizontal direction, and a lower surface connecting the first lower side wall and the second lower side wall to each other. The lower surface extends in the first horizontal direction. In a cross-section taken along the first horizontal direction, the first lower side wall of the second layer and the second lower side wall of the second layer extend to have a constant slope in opposite directions to each other.

According to an embodiment of the present disclosure, a semiconductor device includes a substrate. An active pattern extends in a first horizontal direction on the substrate. First to third nanosheets are sequentially spaced apart from each other and stacked in a vertical direction on the active pattern. A gate electrode extends in a second horizontal direction crossing the first horizontal direction on the active pattern. The gate electrode surrounds each of the first to third nanosheets. A gate spacer is in direct contact with at least a portion of an upper surface of the third nanosheet. The gate spacer extends in the second horizontal direction on both side walls of the gate electrode spaced apart from each other in the first horizontal direction. A source/drain trench is positioned on at least one side of the gate electrode on the active pattern. A source/drain region includes a first layer disposed along side walls and a bottom surface of the source/drain trench, and a second layer disposed on the first layer. The second layer fills the source/drain trench. A thickness in the first horizontal direction of a portion of the first layer overlapping a side wall of the third nanosheet in the first horizontal direction is greater than a thickness in the first horizontal direction of a portion of the first layer overlapping a side wall of the second nanosheet in the first horizontal direction. A thickness in the first horizontal direction of a portion of the first layer overlapping a side wall of the first nanosheet in the first horizontal direction is greater than the thickness in the first horizontal direction of the portion of the first layer overlapping the side wall of the third nanosheet in the first horizontal direction.

According to an embodiment of the present disclosure, a semiconductor device includes a substrate. An active pattern extends in a first horizontal direction on the substrate. First to third nanosheets are sequentially spaced apart from each other and stacked in a vertical direction on the active pattern. Fourth to sixth nanosheets are sequentially spaced apart from each other and stacked in the vertical direction on the active pattern. The fourth to sixth nanosheets are spaced apart from each of the first to third nanosheets in the first horizontal direction. The fourth to sixth nanosheets are disposed at a same vertical level as the first to third nanosheets, respectively. A first gate electrode extends in a second horizontal direction crossing the first horizontal direction on the active pattern. The first gate electrode surrounds each of the first to third nanosheets. A second gate electrode extends in the second horizontal direction on the active pattern. The second gate electrode is spaced apart from the first gate electrode in the first horizontal direction. The second gate electrode surrounds each of the fourth through sixth nanosheets. A first gate spacer is in direct contact with at least a portion of an upper surface of the third nanosheet The first gate spacer extends in the second horizontal direction on both side walls of the first gate electrode spaced apart from each other in the first horizontal direction. A second gate spacer is in direct contact with at least a portion of an upper surface of the sixth nanosheet. The second gate spacer extends in the second horizontal direction on both side walls of the second gate electrode spaced apart from each other in the first horizontal direction. A source/drain trench is positioned between the first gate electrode and the second gate electrode on the active pattern. A source/drain region includes a first layer disposed along side walls and a bottom surface of the source/drain trench, and a second layer disposed on the first layer. The second layer fills the source/drain trench. In a cross-section taken along the first horizontal direction, the second layer includes a first lower side wall facing a side wall of the first nanosheet, a second lower side wall facing a side wall of the fourth nanosheet, and a lower surface connecting the first lower side wall and the second lower side wall to each other. The lower surface extends in the first horizontal direction. In a cross-section taken along the first horizontal direction, each of the first lower side wall of the second layer and the second lower side wall of the second layer extends to have a constant slope in opposite directions to each other. A width in the first horizontal direction of a portion of the second layer overlapping the third nanosheet and the sixth nanosheet in the first horizontal direction is less than a width in the first horizontal direction of a portion of the second layer overlapping the second nanosheet and the fifth nanosheet in the first horizontal direction. A width in the first horizontal direction of a portion of the second layer overlapping the first nanosheet and the fourth nanosheet in the first horizontal direction is less than the width in the first horizontal direction of the portion of the second layer overlapping the third nanosheet and the sixth nanosheet in the first horizontal direction.

### BRIEF DESCRIPTION OF THE DRAWINGS

The above and other aspects and features of the present disclosure will become more apparent by describing in detail embodiments thereof with reference to the attached drawings, in which:

FIG. 1 is a schematic layout diagram for explaining a semiconductor device according to an embodiment of the present disclosure;

FIG. 2 is a cross-sectional view taken along line A-A′ of FIG. 1 according to an embodiment of the present disclosure;

FIG. 3 is an enlarged cross-sectional view of a region R1 of FIG. 2 according to an embodiment of the present disclosure;

FIG. 4 is an enlarged cross-sectional view of a region R2 of FIG. 2 according to an embodiment of the present disclosure;

FIG. 5 is a cross-sectional view taken along line B-B′ of FIG. 1 according to an embodiment of the present disclosure;

FIG. 6 is a plan view taken along line C-C′ of FIG. 2 and viewed from above according to an embodiment of the present disclosure;

FIG. 7 is a plan view taken along line D-D′ of FIG. 2 and viewed from above according to an embodiment of the present disclosure;

FIGS. 8 to 29 are intermediate step diagrams for explaining a method for fabricating a semiconductor device according to some embodiments of the present disclosure;

FIGS. 30 and 31 are plan views for explaining a semiconductor device according to some embodiments of the present disclosure;

FIG. 32 is a cross-sectional view for explaining a semiconductor device according to an embodiment of the present disclosure;

FIG. 33 is an enlarged cross-sectional view of a region R3 of FIG. 32 according to an embodiment of the present disclosure;

FIG. 34 is a cross-sectional view for explaining a semiconductor device according to an embodiment of the present disclosure;

FIGS. 35 and 37 are cross-sectional views for explaining a semiconductor device according to some embodiments of the present disclosure; and

FIG. 36 is an enlarged cross-sectional view of a region R4 of FIG. 35 according to an embodiment of the present disclosure.

### DETAILED DESCRIPTION OF EMBODIMENTS

Although the drawings of a semiconductor device according to some embodiments explain that the semiconductor device includes a transistor including a nanosheet (MBCFET™ (Multi-Bridge Channel Field Effect Transistor)) or a fin-type transistor (FinFET) including a channel region of a fin-type pattern shape, embodiments of the present disclosure are not necessarily limited thereto. In some embodiments, the semiconductor device may, of course, include a tunneling transistor (tunneling FET) or a three-dimensional (3D) transistor. Further, the semiconductor device according to some embodiments may include a bipolar junction transistor, a laterally diffused metal oxide semiconductor (LDMOS), or the like

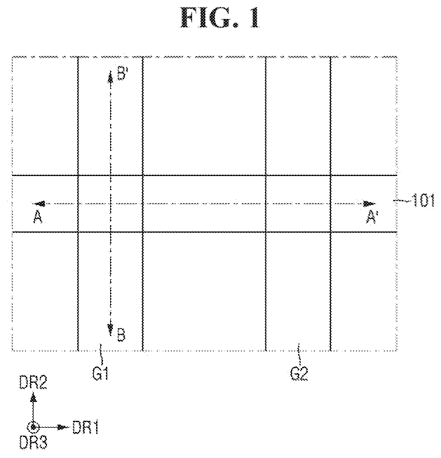

A semiconductor device according to some embodiments of the present disclosure will be described below with reference to FIGS. 1 to 7.

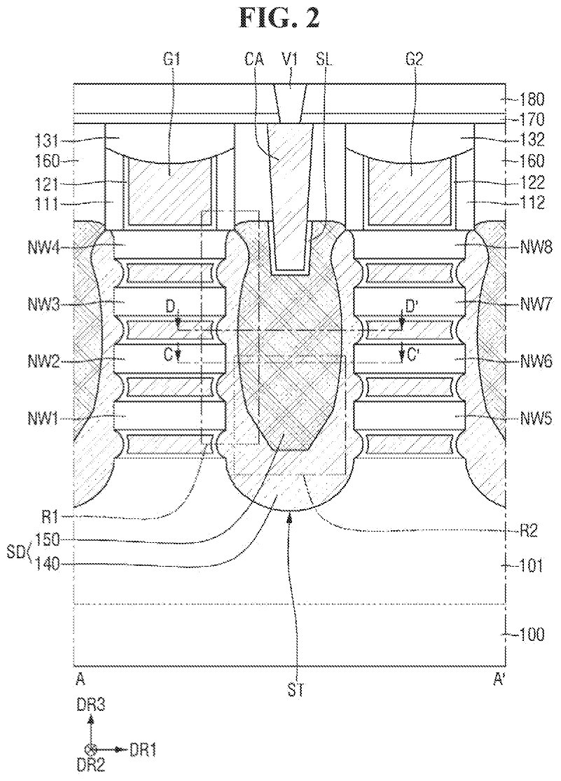

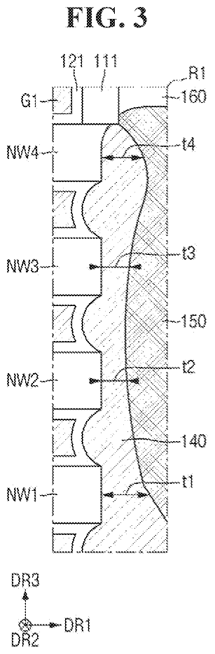

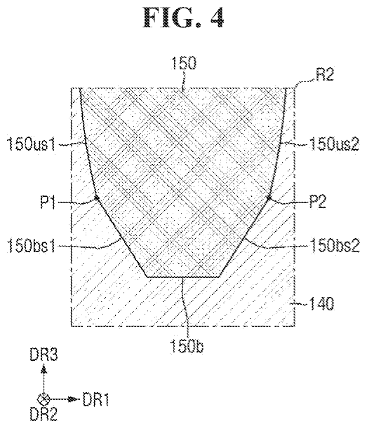

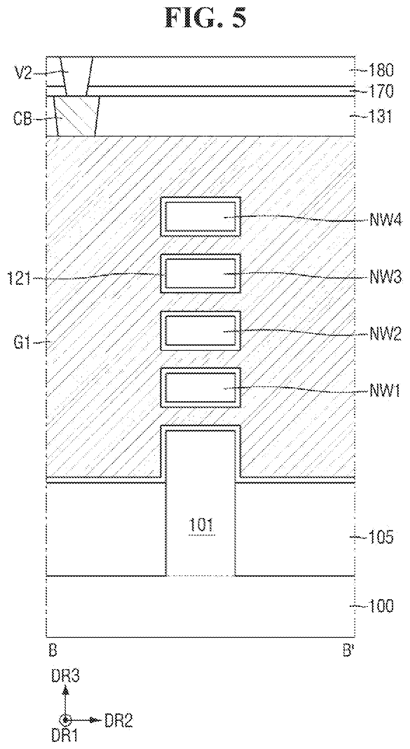

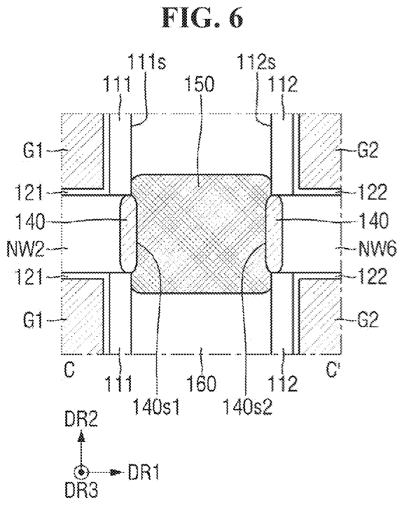

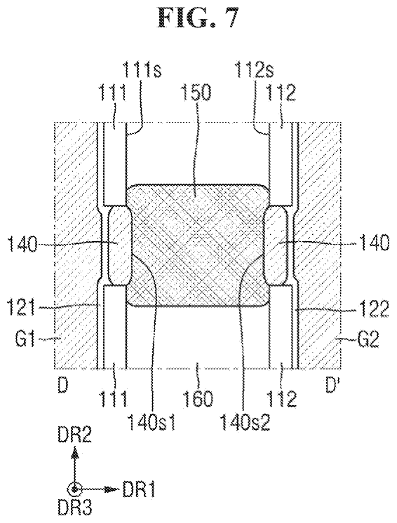

FIG. 1 is a schematic layout diagram for explaining a semiconductor device according to some embodiments of the present disclosure. FIG. 2 is a cross-sectional view taken along line A-A′ of FIG. 1. FIG. 3 is an enlarged view of a region R1 of FIG. 2. FIG. 4 is an enlarged view of a region R2 of FIG. 2. FIG. 5 is a cross-sectional view taken along line B-B′ of FIG. 1. FIG. 6 is a plan view taken along line C-C′ of FIG. 2 and viewed from above. FIG. 7 is a plan view taken along line D-D′ of FIG. 2 and viewed from above.

Referring to FIGS. 1 to 7, a semiconductor device according to some embodiments of the present disclosure includes a substrate 100, an active pattern 101, first to eighth nanosheets NW1 to NW8, first and second gate electrodes G1 and G2, first and second gate spacers 111 and 112, first and second gate insulating layers 121 and 122, first and second capping patterns 131 and 132, a source/drain region SD, a first interlayer insulating layer 160, a source/drain contact CA, a silicide layer SL, a gate contact CB, an etching stop layer 170, a second interlayer insulating layer 180, first and second vias V1 and V2.

In an embodiment, the substrate 100 may be a silicon substrate or silicon-on-insulator (SOI). In some embodiments, the substrate 100 may include silicon germanium, silicon germanium on insulator (SGOI), indium antimonide, lead tellurium compounds, indium arsenic, indium phosphate, gallium arsenide or antimonide gallium. However, embodiments of the present disclosure are not necessarily limited thereto.

Hereinafter, each of a first horizontal direction DR1 and a second horizontal direction DR2 may be defined as a direction parallel to an upper surface of the substrate 100. The second horizontal direction DR2 may be defined as a direction different from the first horizontal direction DR1 and which crosses the first horizontal direction DR1. For example, in an embodiment, the second horizontal direction DR2 may be perpendicular to the first horizontal direction DR1. However, embodiments of the present disclosure are not necessarily limited thereto. A vertical direction DR3 may be defined as a direction perpendicular to each of the first horizontal direction DR1 and the second horizontal direction DR2. For example, the vertical direction DR3 may be defined as a direction perpendicular to the upper surface of the substrate 100.

The active pattern 101 may extend in the first horizontal direction DR1 on the substrate 100. The active pattern 101 may protrude from the upper surface of the substrate 100 in the vertical direction DR3. For example, in an embodiment the active pattern 101 may be a portion of the substrate 100, and may include an epitaxial layer grown from the substrate 100.

In an embodiment, a field insulating layer 105 may be disposed on the upper surface of the substrate 100. The field insulating layer 105 may surround side walls of the active pattern 101. For example, the upper surface of the active pattern 101 may protrude beyond the upper surface of the field insulating layer 105 in the vertical direction DR3. However, embodiments of the present disclosure are not necessarily limited thereto. In some embodiments, the upper surface of the active pattern 101 may be formed on the same plane (e.g., in the vertical direction DR3) as the upper surface of the field insulating layer 105. In an embodiment, the field insulating layer 105 may include, for example, an oxide film, a nitride film, an oxynitride film, or a combination thereof.

First to fourth nanosheets NW1 to NW4 may be disposed on the active pattern 101. The first to fourth nanosheets NW1 to NW4 may be stacked on the active pattern 101 while being sequentially spaced apart from each other in the vertical direction DR3. For example, a first nanosheet NW1 may be spaced apart from the active pattern 101 in the vertical direction DR3 on the active pattern 101. A second nanosheet NW2 may be spaced apart from the first nanosheet NW1 in the vertical direction DR3 on the first nanosheet NW1. A third nanosheet NW3 may be spaced apart from the second nanosheet NW2 in the vertical direction DR3 on the second nanosheet NW2. The fourth nanosheet NW4 may be spaced apart from the third nanosheet NW3 in the vertical direction DR3 on the third nanosheet NW3. For example, the first nanosheet NW1 may be a lowermost nanosheet, and the fourth nanosheet NW4 may be an uppermost nanosheet.

Fifth to eighth nanosheets NW5 to NW8 may be disposed on the active pattern 101. The fifth to eighth nanosheets NW5 to NW8 may be stacked on the active pattern 101 while being sequentially spaced apart from each other in the vertical direction DR3. For example, a fifth nanosheet NW5 may be spaced apart from the active pattern 101 in the vertical direction DR3 on the active pattern 101. A sixth nanosheet NW6 may be spaced apart from the fifth nanosheet NW5 in the vertical direction DR3 on the fifth nanosheet NW5. A seventh nanosheet NW7 may be spaced apart from the sixth nanosheet NW6 in the vertical direction DR3 on the sixth nanosheet NW6. An eighth nanosheet NW8 may be spaced apart from the seventh nanosheet NW7 in the vertical direction DR3 on the seventh nanosheet NW7. For example, the fifth nanosheet NWS may be a lowermost nanosheet, and the eighth nanosheet NW8 may be an uppermost nanosheet. However, embodiments of the present disclosure are not necessarily limited thereto and the number of the nanosheets may vary.

Each of the fifth to eighth nanosheets NW5 to NW8 may be spaced apart from each of the first to fourth nanosheets NW1 to NW4 in the first horizontal direction DR1. In an embodiment, each of the fifth to eighth nanosheets NW5 to NW8 may be disposed at the same vertical level as each of the first to fourth nanosheets NW1 to NW4. For example, the fifth nanosheet NWS may be disposed at the same vertical level as the first nanosheet NW1. The sixth nanosheet NW6 may be disposed at the same vertical level as the second nanosheet NW2. The seventh nanosheet NW7 may be disposed at the same vertical level as the third nanosheet NW3. The eighth nanosheet NW8 may be disposed at the same vertical level as the fourth nanosheet NW4.

Although FIGS. 2 and 5 show that four nanosheets spaced apart and stacked in the vertical direction DR3 are disposed on the active pattern 101, embodiments of the present disclosure are not necessarily limited thereto. For example, in some embodiments, five or more nanosheets may be disposed on the active pattern 101 spaced apart and stacked in the vertical direction DR3. In an embodiment, each of the first to eighth nanosheets NW1 to NW8 may include silicon (Si). However, embodiments of the present disclosure are not necessarily limited thereto. For example, in some embodiments, each of the first through eighth nanosheets NW1 to NW8 may include silicon germanium (SiGe).

The first gate electrode G1 may extend in the second horizontal direction DR2 on the active pattern 101 and the field insulating layer 105. The first gate electrode G1 may surround each of the first to fourth nanosheets NW1 to NW4. The second gate electrode G2 may extend in the second horizontal direction DR2 on the active pattern 101 and the field insulating layer 105. The second gate electrode G2 may be spaced apart from the first gate electrode G1 in the first horizontal direction DR1. The second gate electrode G2 may surround each of the fifth to eighth nanosheets NW5 to NW8.

In an embodiment, each of the first gate electrode G1 and the second gate electrode G2 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. However, embodiments of the present disclosure are not necessarily limited thereto. Each of the first gate electrode G1 and the second gate electrode G2 may include a conductive metal oxide, a conductive metal oxynitride, or the like, and may include oxidized forms of the above materials.

A first gate spacer 111 may be disposed on (e.g., disposed directly thereon in the vertical direction DR3) the upper surface of the fourth nanosheet NW4 and the field insulating layer 105. For example, in an embodiment the first gate spacer 111 may be in direct contact with at least a portion of the upper surface of the fourth nanosheet NW4. The first gate spacer 111 may extend in the second horizontal direction DR2 on both side walls of the first gate electrode G1 that are spaced apart from each other in the first horizontal direction DR1. A second gate spacer 112 may be disposed on the upper surface of the eighth nanosheet NW8 and the field insulating layer 105. For example, in an embodiment the second gate spacer 112 may be in direct contact with at least a portion of the upper surface of the eighth nanosheet NW8. The second gate spacer 112 may extend in the second horizontal direction DR2 on both side walls of the second gate electrode G2 that are spaced apart from each other in the first horizontal direction DR1. In an embodiment, each of the first gate spacer 111 and the second gate spacer 112 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. However, embodiments of the present disclosure are not necessarily limited thereto.

A first gate insulating layer 121 may be disposed between the first gate electrode G1 and the first gate spacer 111. The first gate insulating layer 121 may be disposed between the first gate electrode G1 and a source/drain region SD, which will be described later. The first gate insulating layer 121 may be disposed between the first gate electrode G1 and the active pattern 101. The first gate insulating layer 121 may be disposed between the first gate electrode G1 and the field insulating layer 105. The first gate insulating layer 121 may be disposed between the first gate electrode G1 and the first to fourth nanosheets NW1 to NW4.

A second gate insulating layer 122 may be disposed between the second gate electrode G2 and the second gate spacer 112. The second gate insulating layer 122 may be disposed between the second gate electrode G2 and a source/drain region SD, which will be described later. The second gate insulating layer 122 may be disposed between the second gate electrode G2 and the active pattern 101. The second gate insulating layer 122 may be disposed between the second gate electrode G2 and the field insulating layer 105. The second gate insulating layer 122 may be disposed between the second gate electrode G2 and the fifth to eighth nanosheets NW5 to NW8.

In an embodiment, each of the first gate insulating layer 121 and the second gate insulating layer 122 may include at least one of silicon oxide, silicon oxynitride, silicon nitride, or a high dielectric constant material having a higher dielectric constant than silicon oxide. The high dielectric constant material may include, for example, one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

The semiconductor device according to some embodiments may include an NC (Negative Capacitance) FET that uses a negative capacitor. For example, the first gate insulating layer 121 and the second gate insulating layer 122 may include a ferroelectric material film having ferroelectric properties, and a paraelectric material film having paraelectric properties.

The ferroelectric material film may have a negative capacitance, and the paraelectric material film may have a positive capacitance For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

In an embodiment in which the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 m V/decade at room temperature.

The ferroelectric material film may have ferroelectric properties. In an embodiment, the ferroelectric material film may include, for example, at least one of hafnium oxide, hafnium zirconium oxide, barium strontium titanium oxide, barium titanium oxide, and lead zirconium titanium oxide. However, embodiments of the present disclosure are not necessarily limited thereto. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, in an embodiment the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). However, embodiments of the present disclosure are not necessarily limited thereto. The type of dopant included in the ferroelectric material film may vary, depending on which type of ferroelectric material is included in the ferroelectric material film.

In an embodiment in which the ferroelectric material film includes hafnium oxide, the dopant included in the ferroelectric material film may include, for example, at least one of gadolinium (Gd), silicon (Si), zirconium (Zr), aluminum (Al), and yttrium (Y). However, embodiments of the present disclosure are not necessarily limited thereto.

In an embodiment in which the dopant is aluminum (Al), the ferroelectric material film may include about 3 to about 8 at % (atomic %) aluminum. Here, a ratio of the dopant may be a ratio of aluminum to the sum of hafnium and aluminum.

In an embodiment in which the dopant is silicon (Si), the ferroelectric material film may include about 2 to about 10 at % silicon. In an embodiment in which the dopant is yttrium (Y), the ferroelectric material film may include about 2 to about 10 at % yttrium. In an embodiment in which the dopant is gadolinium (Gd), the ferroelectric material film may include about 1 to about 7 at % gadolinium. In an embodiment in which the dopant is zirconium (Zr), the ferroelectric material film may include about 50 to about 80 at % zirconium.

The paraelectric material film may have the paraelectric properties. In an embodiment, the paraelectric material film may include at least one of, for example, a silicon oxide and a metal oxide having a high dielectric constant. The metal oxide included in the paraelectric material film may include, for example, at least one of hafnium oxide, zirconium oxide, and aluminum oxide. However, embodiments of the present disclosure are not necessarily limited thereto.

The ferroelectric material film and the paraelectric material film may include the same material. The ferroelectric material film has the ferroelectric properties, but the paraelectric material film may not have the ferroelectric properties. For example, in an embodiment in which the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness having the ferroelectric properties. In an embodiment, a thickness of the ferroelectric material film may be, for example, but is not necessarily limited to, about 0.5 to about 10 nm. Since a critical thickness that exhibits the ferroelectric properties may vary for each ferroelectric material, the thickness of the ferroelectric material film may vary depending on the ferroelectric material.

As an example, each of the first gate insulating layer 121 and the second gate insulating layer 122 may include one ferroelectric material film. As another example, each of the first gate insulating layer 121 and the second gate insulating layer 122 may include a plurality of ferroelectric material films spaced apart from each other. In an embodiment, each of the first gate insulating layer 121 and the second gate insulating layer 122 may have a stacked film structure in which the plurality of ferroelectric material films and the plurality of paraelectric material films are alternately stacked.

A first capping pattern 131 may extend in the second horizontal direction DR2 on each of the upper surface of the first gate electrode G1, the uppermost surface of the first gate insulating layer 121, and the uppermost surface of the first gate spacer 111. A second capping pattern 132 may extend in the second horizontal direction DR2 on each of the upper surface of the second gate electrode G2, the uppermost surface of the second gate insulating layer 122, and the uppermost surface of the second gate spacer 112. For example, in an embodiment the first capping pattern 131 may be in direct contact with the uppermost surface of the first gate spacer 111, the first gate insulating layer 121 and the first gate electrode G1 and the second capping pattern 132 may be in direct contact with the uppermost surface of the second gate spacer 112, the second gate insulating layer 122 and the second gate electrode G2. However, embodiments of the present disclosure are not necessarily limited thereto. For example, in some embodiments, the first capping pattern 131 may be disposed between the first gate spacers 111, and the second capping pattern 132 may be disposed between the second gate spacers 112. In an embodiment, each of the first capping pattern 131 and the second capping pattern 132 may include, for example, at least one of silicon nitride (SiN), silicon oxynitride (SiON), silicon oxide (SiO₂), silicon carbonitride (SiCN), silicon oxycarbonitride (SiOCN), and combinations thereof. However, embodiments of the present disclosure are not necessarily limited thereto.

A source/drain trench ST may be formed on at least one side of each of the first gate electrode G1 and the second gate electrode G2 on the active pattern 101. For example, in an embodiment the source/drain trench ST may be formed on both sides of each of the first gate electrode G1 and the second gate electrode G2. For example, the source/drain trench ST may be formed between the first gate electrode G1 and the second gate electrode G2 (e.g., in the first direction DR1). For example, at least a portion of the source/drain trench ST may extend into the active pattern 101.

The source/drain region SD may be disposed inside the source/drain trench ST. For example, in an embodiment the source/drain regions SD may be disposed on both sides of each of the first gate electrode G1 and the second gate electrode G2. For example, the source/drain region SD may be disposed between the first gate electrode G1 and the second gate electrode G2 (e.g., in the first direction DR1). For example, in an embodiment the upper surface of the source/drain region SD may be formed to be higher (e g., in the third direction DR3) than the upper surface of the fourth nanosheet NW4 and the upper surface of the eighth nanosheet NW8. In an embodiment, the source/drain region SD may include a first layer 140, and a second layer 150 disposed on the first layer 140 (e.g., disposed directly thereon).

The first layer 140 may be disposed along side walls and a bottom surface of the source/drain trench ST. The first layer 140 may be in direct contact with each of the active pattern 101, the first gate insulating layer 121, and the second gate insulating layer 122. The first layer 140 may be in direct contact with side walls in the first horizontal direction DR1 of each of the first to eighth nanosheets NW1 to NW8. The first layer 140 may be in direct contact with each of the first gate spacer 111 and the second gate spacer 112.

For example, in an embodiment a thickness t4 in the first horizontal direction DR1 of the first layer 140 disposed on the side walls of the fourth nanosheet NW4 may be greater than each of a thickness t2 in the first horizontal direction DR1 of the first layer 140 disposed on the side walls of the second nanosheet NW2, and a thickness t3 in the first horizontal direction DR1 of the first layer 140 disposed on the side walls of the third nanosheet NW3. For example, the thickness t1 in the first horizontal direction DR1 of the first layer 140 disposed on the side walls of the first nanosheet NW1 may be greater than each of the thickness t2 in the first horizontal direction DR1 of the first layer 140 disposed on the side walls of the second nanosheet NW2, and the thickness t3 in the first horizontal direction DR1 of the first layer 140 disposed on the side walls of the third nanosheet NW3. Further, the thickness t1 in the first horizontal direction DR1 of the first layer 140 disposed on the side wall of the first nanosheet NW1 may be greater than the thickness t4 in the first horizontal direction DR1 of the first layer 140 disposed on the side wall of the fourth nanosheet NW4.

The thickness of the first layer 140 disposed on side walls of each of the fifth to eighth nanosheets NWS to NW8 may be formed to be similar to the thicknesses of the first layer 140 disposed on side walls of each of the first to fourth nanosheets NW1 to NW4. In an embodiment, the first layer 140 may include, for example, silicon germanium (SiGe). The first layer 140 may include doped P-type impurities. For example, in an embodiment the P-type impurities may be boron (B) or carbon (C). However, embodiments of the present disclosure are not necessarily limited thereto.

As shown in FIG. 6, for example, on the side wall of the second nanosheet NW2 (e.g., overlapping the side wall of the second nanosheet NW2 in the first horizontal direction DR1), a first side wall 140s1 of the first layer 140 in direct contact with the second layer 150 may protrude further towards the second layer 150 (e.g., in the first direction DR1) beyond a side wall 111s of the first gate spacer 111 in direct contact with the second layer 150. Also, for example, on the side wall of the sixth nanosheet NW6 (e.g., overlapping the side wall of the sixth nanosheet NW6 in a direction opposite to the first horizontal direction DR1), a second side wall 140s2 of the first layer 140 in direct contact with the second layer 150 may protrude further towards the second layer 150 (e.g., in a direction opposite to the first direction DR1) beyond a side wall 112s of the second gate spacer 112 in direct contact with the second layer 150.

As shown in FIG. 7, for example, on the side wall of the first gate electrode G1 in contact with the second nanosheet NW2, the first side wall 140s1 of the first layer 140 in direct contact with the second layer 150 may protrude further towards the second layer 150 (e.g., in the first direction DR1) beyond the side wall 111s of the first gate spacer 111 in direct contact with the second layer 150. Further, for example, on the side wall of the second gate electrode G2 in contact with the sixth nanosheet NW6, the second side wall 140s2 of the first layer 140 in direct contact with the second layer 150 may protrude further towards the second layer 150 (e.g., in a direction opposite to the first direction DR1) beyond the side wall 112s of the second gate spacer 112 in direct contact with the second layer 150

The second layer 150 may be disposed on the first layer 140 and may fill the inside of the source/drain trench ST. The second layer 150 may be in direct contact with the first layer 140. For example, the second layer 150 may be in direct contact with each of the first gate spacer 111 and the second gate spacer 112. For example, the upper surface of the second layer 150 may be formed to be higher (e.g., in the third direction DR3) than each of the upper surface of the fourth nanosheet NW4 and the upper surface of the eighth nanosheet NW8.

For example, a width in the first horizontal direction DR1 of the second layer 150 disposed between the fourth nanosheet NW4 and the eighth nanosheet NW8 (e.g., in the first horizontal direction DR1) may be less than each of a width in the first horizontal direction DR1 of the second layer 150 disposed between the third nanosheet NW3 and the seventh nanosheet NW7 (e.g., in the first horizontal direction DR1), and a width in the first horizontal direction DR1 of the second layer 150 disposed between the second nanosheet NW2 and the sixth nanosheet NW6 (e.g., in the first horizontal direction DR1). For example, the width in the first horizontal direction DR1 of the second layer 150 disposed between the first nanosheet NW1 and the fifth nanosheet NW5 (e.g., in the first horizontal direction DR1) may be less than each of the width in the first horizontal direction DR1 of the second layer 150 disposed between the third nanosheet NW3 and the seventh nanosheet NW7 (e.g., in the first horizontal direction DR1), and the width in the first horizontal direction DR1 of the second layer 150 disposed between the second nanosheet NW2 and the sixth nanosheet NW6 (e.g., in the first horizontal direction DR1). Also, the width in the first horizontal direction DR1 of the second layer 150 disposed between the first nanosheet NW1 and the fifth nanosheet NW5 (e.g., in the first horizontal direction DR1) may be less than the width in the first horizontal direction DR1 of the second layer 150 disposed between the fourth nanosheet NW4 and the eighth nanosheet NW8 (e.g., in the first horizontal direction DR1).

As shown in FIGS. 2 and 4, in a cross-section taken along the first horizontal direction DR1, the second layer 150 may include a first lower side wall 150bs1, a second lower side wall 150bs2, a first upper side wall 150us1, a second upper side wall 150us2, and a lower surface 150b.

The first lower side wall 150bs1 of the second layer 150 may be a surface that faces the side wall of the first nanosheet NW1. The second lower side wall 150bs2 of the second layer 150 may be a surface that faces the side wall of the fifth nanosheet NW5. The second lower side wall 150bs2 of the second layer 150 may be opposite to the first lower side wall 150bs1 of the second layer 150 in the first horizontal direction DR1.

For example, in an embodiment, in a cross-section taken along the first horizontal direction DR1, each of the first lower side wall 150bs1 of the second layer 150 and the second lower side wall 150bs2 of the second layer 150 may extend to have a constant slope in opposite directions to each other. For example, the first lower side wall 150bs1 of the second layer 150 may extend to have a constant slope towards the side wall of the first nanosheet NW1. The second lower side wall 150bs2 of the second layer 150 may extend to have a constant slope towards the side wall of the fifth nanosheet NW5. For example, in a cross-section taken along the first horizontal direction DR1, each of the first lower side wall 150bs1 of the second layer 150 and the second lower side wall 150bs2 of the second layer 150 may be shown as a straight line. However, embodiments of the present disclosure are not necessarily limited thereto.

In a cross-section taken along the first horizontal direction DR1, the lower surface 150b of the second layer 150 may be a surface that connects the first lower side wall 150bs1 of the second layer 150 and the second lower side wall 150bs2 of the second layer 150 to each other. In an embodiment, in a cross-section taken along the first horizontal direction DR1, the lower surface 150b of the second layer 150 may be shown as a straight line that connects the first lower side wall 150bs1 of the second layer 150 and the second lower side wall 150bs2 of the second layer 150 to each other. In a cross-section taken along the first horizontal direction DR1, each of the first lower side wall 150bs1 of the second layer 150 and the second lower side wall 150bs2 of the second layer 150 may extend to have an acute angle with respect to the lower surface 150b of the second layer 150.

The first upper side wall 150us1 of the second layer 150 may be a surface that faces the side wall of the second nanosheet NW2. The second upper side wall 150us2 of the second layer 150 may be a surface that faces the side wall of the sixth nanosheet NW6. The second upper side wall 150us2 of the second layer 150 may be opposite to the first upper side wall 150us1 of the second layer 150 in the first horizontal direction DR1.

For example, in an embodiment, in a cross-section taken along the first horizontal direction DR1, the first upper side wall 150us1 of the second layer 150 may be shown as a curved line. The first upper side wall 150us1 of the second layer 150 may be connected with the first lower side wall 150bs1 of the second layer 150. A position at which the first upper side wall 150us1 of the second layer 150 and the first lower side wall 150bs1 of the second layer 150 are directly connected to each other may be defined as a first connecting position P1. For example, in an embodiment the first connecting position P1 may overlap each of the first nanosheet NW1 and the fifth nanosheet NW5 in the first horizontal direction DR1.

For example, in a cross-section taken along the first horizontal direction DR1, the second upper side wall 150us2 of the second layer 150 may be shown as a curved line. The second upper side wall 150us2 of the second layer 150 may be directly connected with the second lower side wall 150bs2 of the second layer 150. A position at which the second upper side wall 150us2 of the second layer 150 and the second lower side wall 150bs2 of the second layer 150 are directly connected with each other may be defined as a second connecting position P2. For example, in an embodiment the second connecting position P2 may overlap each of the first nanosheet NW1 and the fifth nanosheet NW5 in the first horizontal direction DR1.

In an embodiment, the second layer 150 may include, for example, silicon germanium (SiGe). For example, the concentration of germanium (Ge) included in the second layer 150 may be greater than the concentration of germanium (Ge) included in the first layer 140. The second layer 150 may include doped P-type impurities. For example, in an embodiment the P-type impurities may be boron (B) or carbon (C). However, embodiments of the present disclosure are not necessarily limited thereto.

A first interlayer insulating layer 160 may be disposed on the field insulating layer 105. The first interlayer insulating layer 160 may cover the source/drain region SD. The first interlayer insulating layer 160 may surround side walls of each of the first gate spacer 111, the second gate spacer 112, the first capping pattern 131 and the second capping pattern 132. For example, the upper surface of the first interlayer insulating layer 160 may be formed on the same plane (e.g, in the vertical direction DR3) as the upper surfaces of each of the first capping pattern 131 and the second capping pattern 132. However, embodiments of the present disclosure are not necessarily limited thereto. For example, in some embodiments the first interlayer insulating layer 160 may cover the upper surface of each of the first capping pattern 131 and the second capping pattern 132.

In an embodiment, the first interlayer insulating layer 160 may include, for example, at least one of silicon oxide, silicon nitride, silicon oxynitride, and a low dielectric constant material. Although the low dielectric constant material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof, embodiments of the present disclosure are not necessarily limited thereto.

A source/drain contact CA may be disposed between the first gate electrode G1 and the second gate electrode G2 (e.g., in the first direction DR1). The source/drain contact CA penetrates the first interlayer insulating layer 160 in the vertical direction DR3, and may be connected to the source/drain region SD. For example, the source/drain contact CA may be connected to the second layer 150. For example, at least a portion of the source/drain contact CA may extend into the second layer 150. For example, the upper surface of the source/drain contact CA may be formed on the same plane (e.g., in the vertical direction DR3) as the upper surface of the first interlayer insulating layer 160. In FIG. 2, although the source/drain contact CA is shown as being formed of a single film, embodiments of the present disclosure are not necessarily limited thereto. In some embodiments, the source/drain contact CA may be formed of multiple films.

In an embodiment, the source/drain contact CA may include, for example, at least one of tantalum (Ta), tantalum nitride (TaN), titanium (Ti), titanium nitride (TiN), ruthenium (Ru), cobalt (Co), nickel (Ni), nickel boron (NiB), tungsten (W), tungsten nitride (WN), zirconium (Zr), zirconium nitride (ZrN), vanadium (V), vanadium nitride (VN), niobium (Nb), niobium nitride (NbN), platinum (Pt), iridium (Ir), rhodium (Rh), aluminum (Al), copper (Cu), and molybdenum (Mo). However, embodiments of the present disclosure are not necessarily limited thereto.

A silicide layer SL may be disposed between the source/drain contact CA and the source/drain region SD. For example, the silicide layer SL may be disposed between the source/drain contact CA and the second layer 150. In an embodiment, the silicide layer SL may include, for example, a metal silicide material.

For example, the gate contact CB penetrates the first capping pattern 131 in the vertical direction DR3, and may be connected (e.g., electrically connected) to the first gate electrode G1. For example, in an embodiment the upper surface of the gate contact CB may be formed on the same plane (e.g., in the vertical direction DR3) as the upper surfaces of each of the first capping pattern 131 and the first interlayer insulating layer 160. In FIG. 5, although the gate contact CB is shown as being formed of a single film, embodiments of the present disclosure are not necessarily limited thereto. In some embodiments, the gate contact CB may be formed of multiple films.

In an embodiment, the gate contact CB may include, for example, at least one of tantalum (Ta), tantalum nitride (TaN), titanium (Ti), titanium nitride (TiN), ruthenium (Ru), cobalt (Co), nickel (Ni), nickel boron (NiB), tungsten (W), tungsten nitride (WN), zirconium (Zr), zirconium nitride (ZrN), vanadium (V), vanadium nitride (VN), niobium (Nb), niobium nitride (NbN), platinum (Pt), iridium (Ir), rhodium (Rh), aluminum (Al), copper (Cu) and molybdenum (Mo). However, embodiments of the present disclosure are not necessarily limited thereto.

The etching stop layer 170 may be disposed on (e.g., disposed directly thereon) upper surfaces of each of the first interlayer insulating layer 160, the first capping pattern 131, the second capping pattern 132, the source/drain contact CA, and the gate contact CB. Although FIGS. 2 and 5 show that the etching stop layer 170 is formed of a single film, embodiments of the present disclosure are not necessarily limited thereto. For example, in some embodiments, the etching stop layer 170 may be formed of multiple films. In an embodiment, the etching stop layer 170 may include, for example, at least one of aluminum oxide, aluminum nitride, hafnium oxide, zirconium oxide, silicon oxide, silicon nitride, silicon oxynitride, and a low dielectric constant material. The second interlayer insulating layer 180 may be disposed on (e.g., disposed directly thereon) the etching stop layer 170. In an embodiment, the second interlayer insulating layer 180 may include, for example, at least one of silicon oxide, silicon nitride, silicon oxynitride, and a low dielectric constant material.

A first via V1 penetrates the second interlayer insulating layer 180 and the etching stop layer 170 in the vertical direction DR3, and may be connected to the source/drain contact CA. In an embodiment, the second via V2 penetrates the second interlayer insulating layer 180 and the etching stop layer 170 in the vertical direction DR3, and may be connected to (e.g., directly connected thereto) the gate contact CB. Although FIGS. 2 and S show that each of the first via V1 and the second via V2 is formed of a single film, embodiments of the present disclosure are not necessarily limited thereto. In some embodiments, each of the first via V1 and the second via V2 may be formed of multiple films. Each of the first via V1 and the second via V2 may include a conductive material.

The semiconductor device according to some embodiments of the present disclosure may prevent a short-circuit from occurring between the first gate the electrode G1 and the second layer 150, by forming each of a thickness t1 of the first layer 140 disposed on the side walls of the first nanosheet NW1 as the lowermost nanosheet, and a thickness t4 of the first layer 140 disposed on the side walls of the fourth nanosheet NW4 as the uppermost nanosheet to be greater than the thicknesses t2 and t3 of the first layer 140 disposed on the side walls of the central nanosheets NW2 and NW3.

Also, the semiconductor device according to some embodiments of the present disclosure may increase a region in which the second layer 150 is disposed to increase the performance of the semiconductor device, by forming each of the thickness t1 of the first layer 140 disposed on the side walls of the first nanosheet NW1 as the lowermost nanosheet, and the thicknesses t4 of the first layer 140 disposed on the side walls of the fourth nanosheet NW4 as the uppermost nanosheet to be greater than the thicknesses t2 and t3 of the first layer 140 disposed on the side walls of the central nanosheets NW2 and NW3.

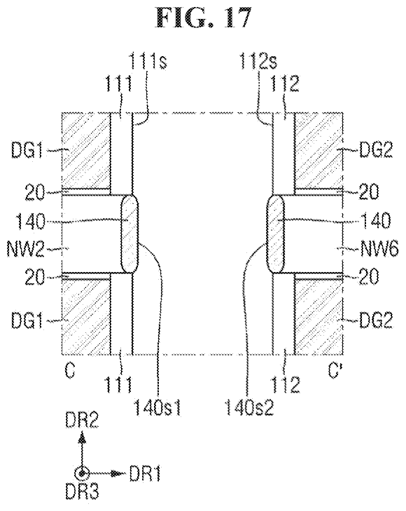

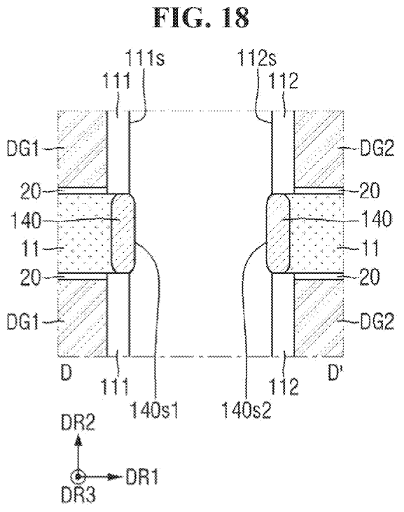

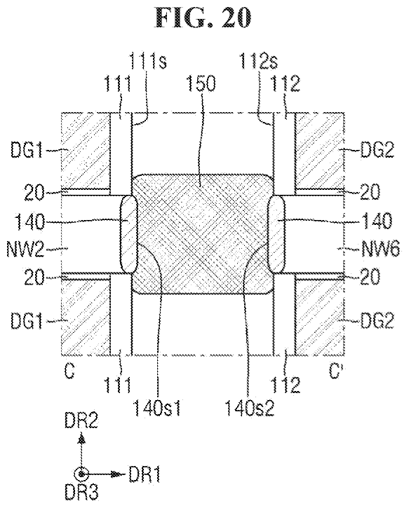

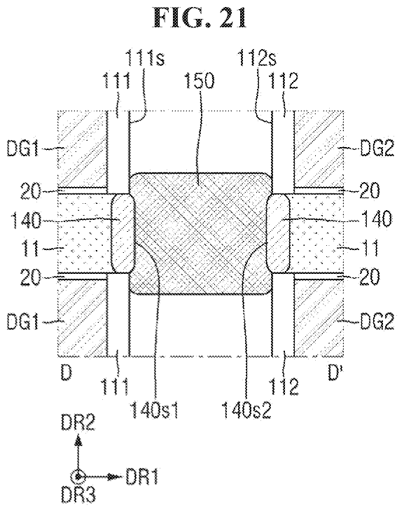

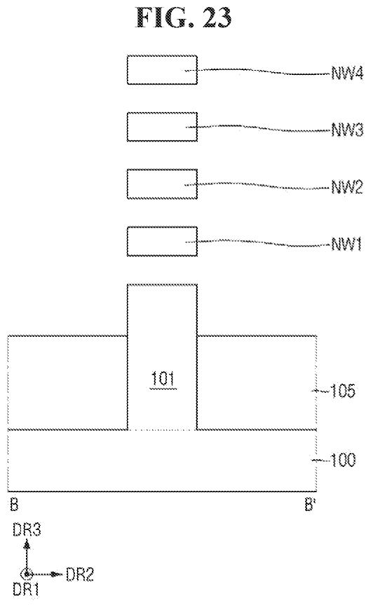

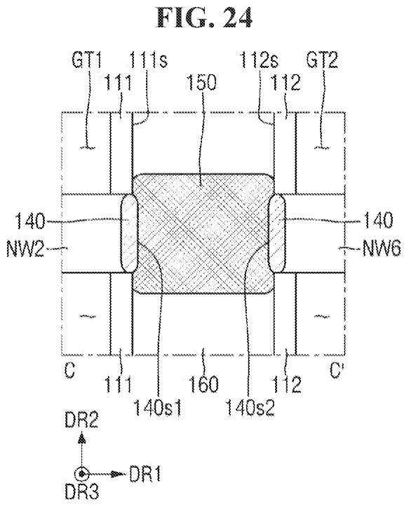

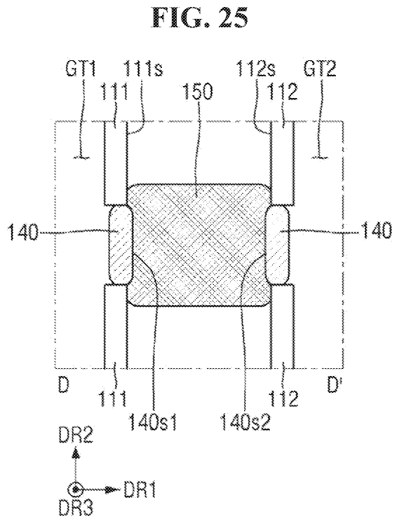

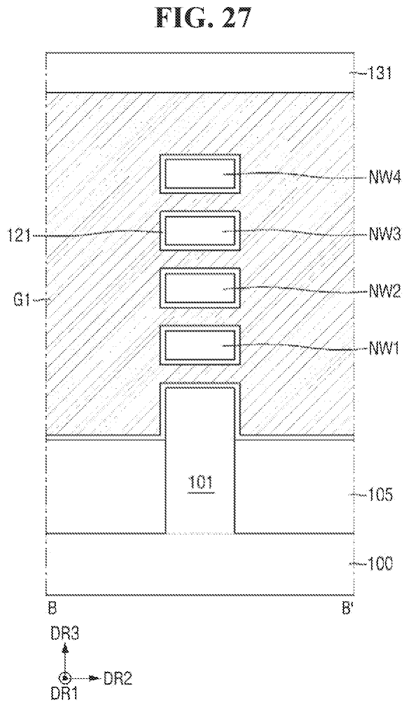

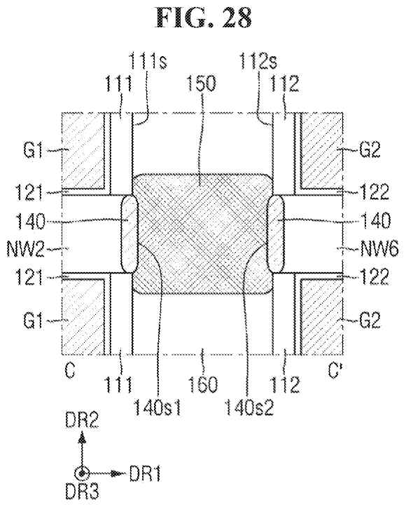

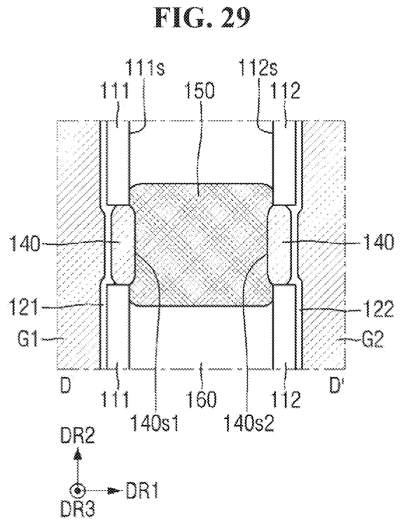

A method of fabricating a semiconductor device according to some embodiments of the present disclosure will be described below with reference to FIGS. 2 to 29.

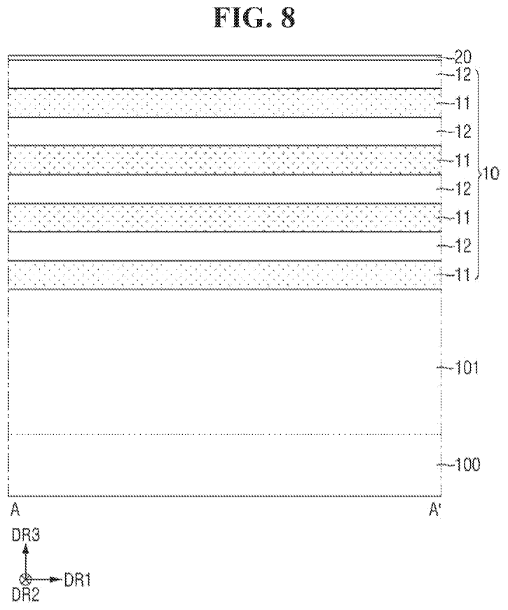

FIGS. 8 to 29 are intermediate step diagrams for explaining the method of fabricating the semiconductor device according to some embodiments of the present disclosure.

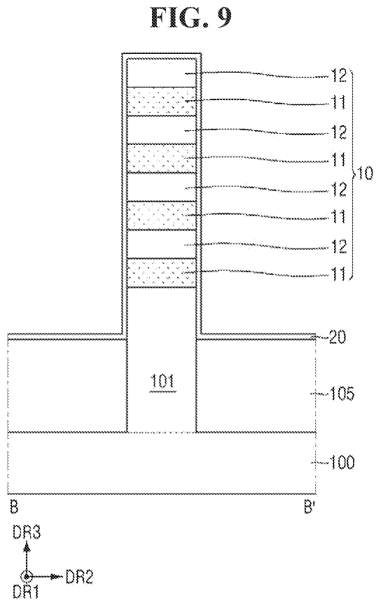

Referring to FIGS. 8 and 9, a stacked structure 10 may be formed on the substrate 100. The stacked structure 10 may include a sacrificial layer 11 and a semiconductor layer 12 that are alternately stacked on the substrate 100 (e.g., in the vertical direction DR3). For example, the sacrificial layer 11 may be formed at the lowermost portion of the stacked structure 10, and the semiconductor layer 12 may be formed at the uppermost portion of the stacked structure 10. However, embodiments of the present disclosure are not necessarily limited thereto. In some embodiments, the sacrificial layer 11 may also be formed at the uppermost portion of the stacked structure 10. In an embodiment, the sacrificial layer 11 may include, for example, silicon germanium (SiGe). The semiconductor layer 12 may include, for example, silicon (Si).

A portion of the stacked structure 10 may then be etched. A portion of the substrate 100 may also be etched, while the stacked structure 10 is being etched. Through such an etching process, an active pattern 101 may be defined under the stacked structure 10 on the upper surface of the substrate 100. The active pattern 101 may extend in the first horizontal direction DR1. The field insulating layer 105 may then be formed on (e.g., formed directly thereon) the upper surface of the substrate 100. The field insulating layer 105 may surround a portion of the side walls of the active pattern 101 and directly contact a portion of the side walls of the active pattern 101. For example, the upper face of the active pattern 101 may be formed to be higher than the upper surface of the field insulating layer 105 (e.g, in the vertical direction DR3).

A pad oxide layer 20 may then be formed to cover the upper surface of the field insulating layer 105, the side walls of the exposed active pattern 101, and the side walls and the upper surface of the stacked structure 10. For example, the pad oxide layer 20 may be formed conformally. In an embodiment, the pad oxide layer 20 may include, for example, silicon oxide (SiO₂).

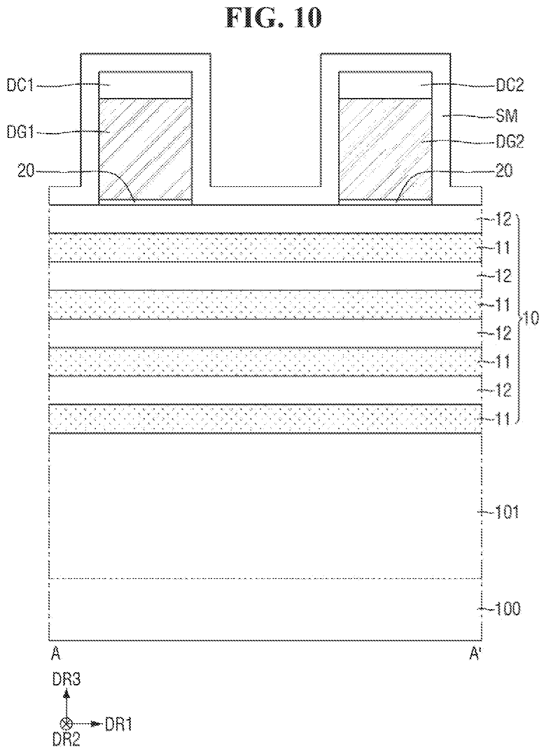

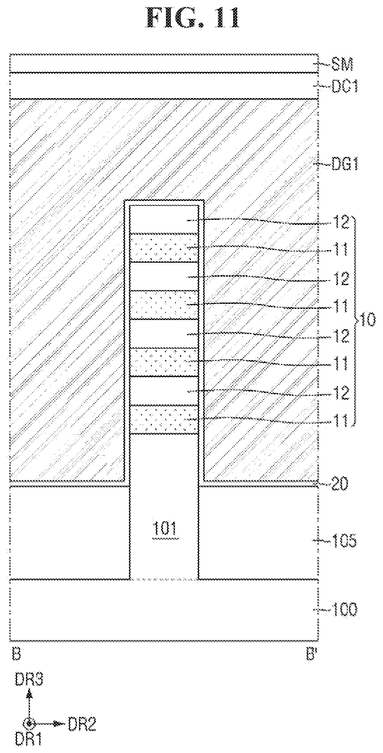

Referring top FIGS. 10 and 11, first and second dummy gates DG1 and DG2 and first and second dummy capping patterns DC1 and DC2 extending in the second horizontal direction DR2 on the pad oxide layer 20 on the stacked structure 10 and the field insulating layer 105 may be formed. The first dummy capping pattern DC1 may be formed on the first dummy gate DG1 (e.g., formed directly thereon in the vertical direction DR3). Also, the second dummy capping pattern DC2 may be formed on the second dummy gate DG2 (e.g., formed directly thereon in the vertical direction DR3). Each of the second dummy gate DG2 and the second dummy capping pattern DC2 may be spaced apart from each of the first dummy gate DG1 and the first dummy capping pattern DC1 in the first horizontal direction DR1.

In an embodiment, while the first and second dummy gates DG1 and DG2 and the first and second dummy capping patterns DC1 and DC2 are being formed, a remaining pad oxide layer 20 except for the portion that overlaps each of the first and second dummy gates DG1 and DG2 on the substrate 100 in the vertical direction DR3 may be removed.

A spacer material layer SM may then be formed to cover the side walls of each of the first and second dummy gates DG1 and DG2, the side walls and upper surfaces of each of the first and second dummy capping patterns DC1 and DC2, side walls and upper surface of the exposed stacked structure 10, and the upper surface of the field insulating layer 105. For example, in an embodiment the spacer material layer SM may be formed conformally. In an embodiment, the spacer material layer (SM) may include, for example, at least one of silicon nitride (SiN), silicon oxycarbonitride (SiOCN), silicon boron carbonitride (SiBCN), silicon carbonitride (SiCN), silicon oxynitride (SiON), and combinations thereof. However, embodiments of the present disclosure are not necessarily limited thereto.

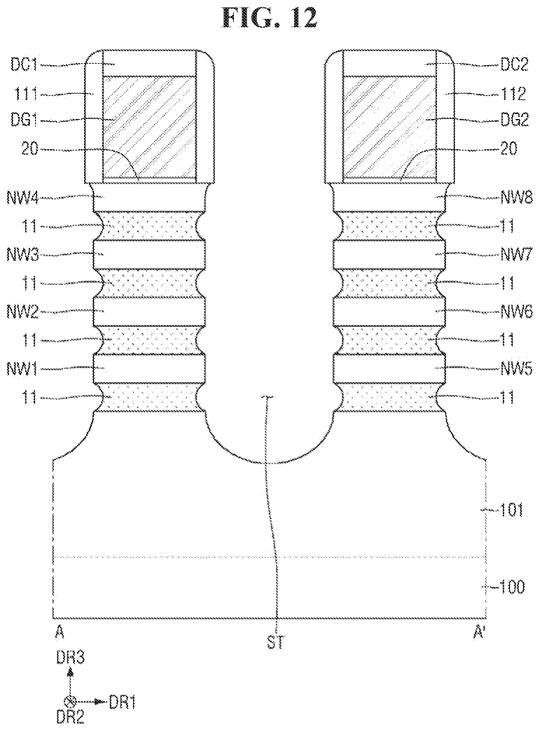

Referring to FIG. 12, the stacked structure 10 (FIGS. 10 and 11) may be etched using the first and second dummy capping patterns DC1 and DC2 and the first and second dummy gates DG1 and DG2 as masks, thereby forming a source/drain trench ST. For example, the source/drain trench ST may extend into the inside of the active pattern 101.

During the formation of the source/drain trench ST, a spacer material layer SM (FIGS. 10 and 11) formed on upper surfaces of each of the first and second dummy capping patterns DC1 and DC2, and each of the first and second dummy capping patterns DC1 and DC2 may be partially removed. The spacer material layer SM (FIGS. 10 and 11) remaining on side walls of each of the first dummy capping pattern DC1 and the first dummy gate DG1 may be defined as a first gate spacer 111. Further, the spacer material layer SM (FIGS. 10 and 11) that remains on the side walls of each of the second dummy capping pattern DC2 and the second dummy gate DG2 may be defined as a second gate spacer 112.

After the source/drain trench ST is formed, the semiconductor layer 12 (FIGS. 10 and 11) that remains below the first dummy gate DG1 may be defined as first to fourth nanosheets NW1 to NW4. Also, after the source/drain trench ST is formed, the semiconductor layer 12 (FIGS. 10 and 11) that remains below the second dummy gate DG2 may be defined as fifth to eighth nanosheets NW5 to NW8.

For example, the sacrificial layer 11 may be etched further beyond the semiconductor layer 12 (FIGS. 10 and 11) while the source/drain trench ST is being formed. As a result, the side walls of the sacrificial layer 11 may be formed to be recessed beyond the side walls of each of the first to eighth nanosheets NW1 to NW8.

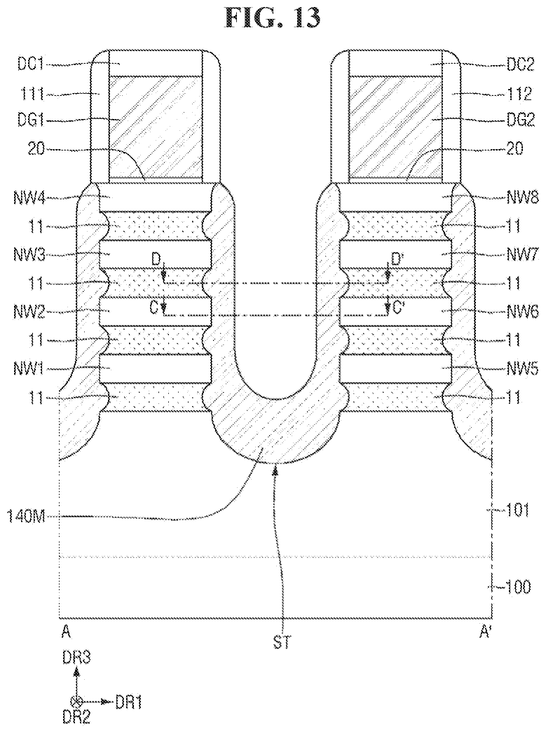

Referring to FIGS. 13 to 15, a source/drain material layer 140M may be formed along side walls and a bottom surface of the source/drain trench ST. For example, the source/drain material layer 140M may be in direct contact with each of the active pattern 101, the side walls of the sacrificial layer 11 in the first horizontal direction DR1, the side walls of each of the first to eighth nanosheets NW1 to NW8 in the first horizontal direction DR1, and each of the first and second gate spacers 111 and 112. For example, in an embodiment the source/drain material layer 140M may include silicon germanium (SiGe) doped with P-type impurities. However, embodiments of the present disclosure are not necessarily limited thereto.

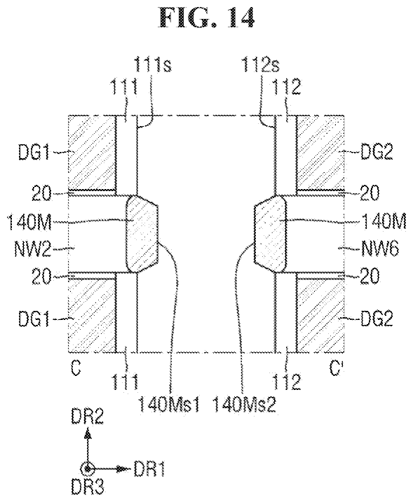

As shown in FIG. 14, for example, on the side walls of the second nanosheet NW2 (e.g., overlapping the side walls of the second nanosheet NW2 in the first horizontal direction DR1), the first side walls 140Ms1 of the exposed source/drain material layer 140M may protrude further beyond the side wall 111s of the exposed first gate spacer 111 (e.g., in the first direction DR1). Also, for example, on the side walls of the sixth nanosheet NW6 (e.g., overlapping the side walls of the second nanosheet NW2 in the first horizontal direction DR1), the second side walls 140Ms2 of the exposed source/drain material layer 140M may protrude further beyond the side walls 112s of the exposed second gate spacer 112 (e.g., in a direction opposite to the first direction DR1).

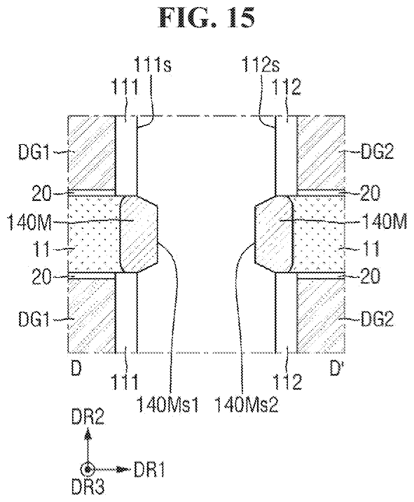

As shown in FIG. 15, for example, on the side walls of the sacrificial layer 11 surrounded by the first dummy gate DG1 (e.g., overlapping in the first horizontal direction DR1), the first side walls 140Ms1 of the exposed source/drain material layer 140M may protrude further beyond the side walls 111s of the exposed first gate spacer 111 (e.g., in the first direction DR1). Also, for example, on the side walls of the sacrificial layer 11 surrounded by the second dummy gate DG2 (e.g., overlapping in the first horizontal direction DR1), the second side walls 140Ms2 of the exposed source/drain material layer 140M may protrude further beyond the side walls 112s of the exposed second gate spacer 112 (e.g., in a direction opposite to the first direction DR1)

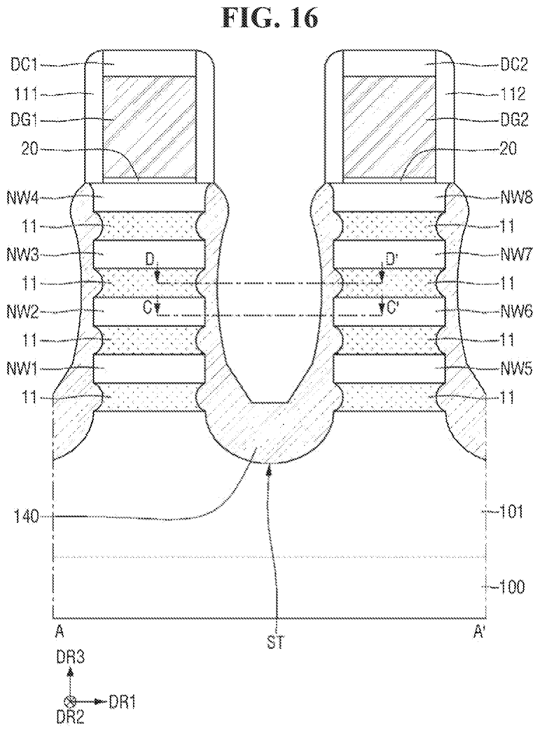

Referring to FIGS. 16 to 18, the source/drain material layer 140M (FIGS. 13 to 15) may be sequentially subjected to an etch-back process and an annealing process. Accordingly, a portion of the exposed surface of the source/drain material layer 140M (FIGS. 13 to 15) may be etched. The source/drain material layer 140M (FIGS. 13 to 15) in which a portion of the exposed surface remains after etched may be defined as a first layer 140. After the etch-back process and the annealing process are performed, the surface of the exposed first layer 140 may have a shape like an interface between the first layer 140 and the second layer 150 shown in FIGS. 3 and 4.

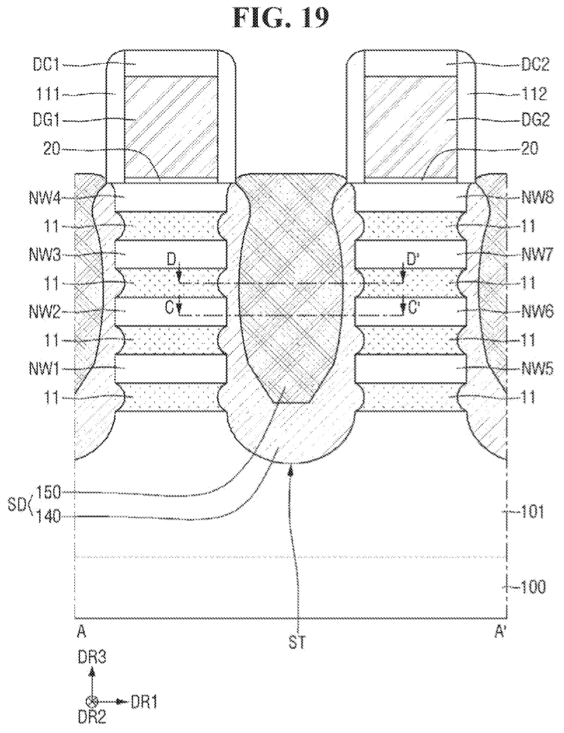

Referring to FIGS. 19 to 21, a second layer 150 may be formed on (e.g., formed directly thereon) the first layer 140 to fill the inside of the source/drain trench ST. Therefore, the source/drain region SD including the first layer 140 and the second layer 150 may be formed.

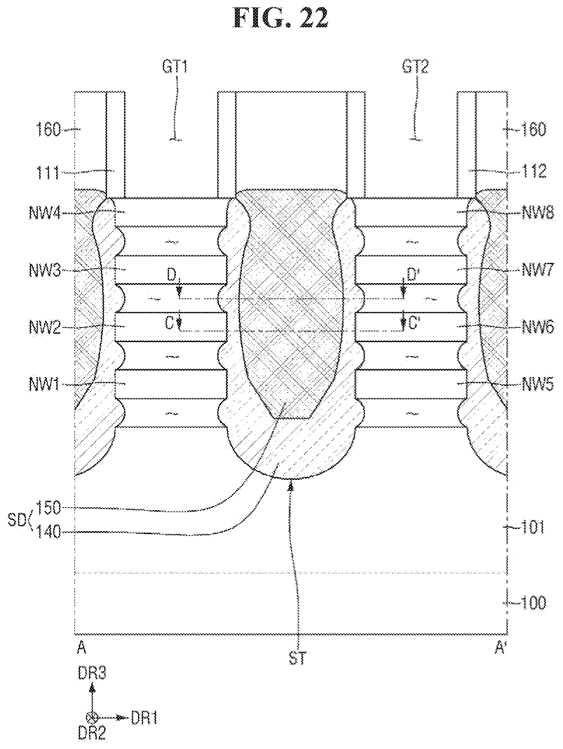

Referring to FIGS. 22 to 25, the first interlayer insulating layer 160 may be formed to cover the side walls and upper surface of the source/drain region SD, the first and second gate spacers 111 and 112, and each of the first and second dummy capping patterns DC1 and DC2 (FIG. 19). The upper surfaces of each of the first and second dummy gates (DG1, DG2 of FIG. 19) may then be exposed through a planarization process.

In an embodiment, each of the first and second dummy gates (DG1 and DG2 of FIGS. 19 to 21), the pad oxide layer (20 of FIGS. 19 to 21) and the sacrificial layer (11 of FIGS. 19 to 21) may then be etched. A portion from which the first dummy gate (DG1 of FIGS. 19 to 21) is removed may be defined as a first gate trench GT1. A portion from which the second dummy gate (DG2 of FIGS. 19 to 21) is removed may be defined as a second gate trench GT2.

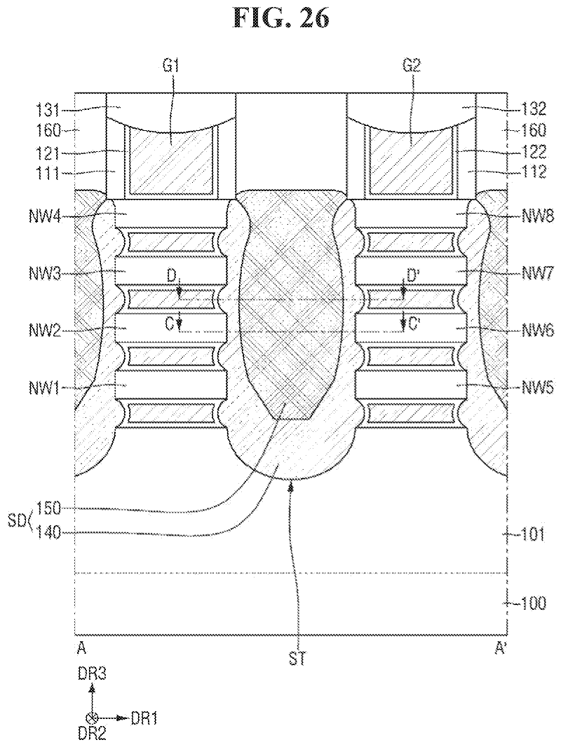

Referring to FIGS. 26 to 29, the first gate insulating layer 121, the first gate electrode G1, and the first capping pattern 131 may be sequentially formed in the portion in which the first dummy gate DG1 (FIGS. 19 to 21), the pad oxide layer 20 (FIGS. 19 to 21) and the sacrificial layer 11 (FIGS. 19 to 21) are etched. In addition, the second gate insulating layer 122, the second gate electrode G2, and the second capping pattern 132 may be sequentially formed in the portion in which the second dummy gate DG2 (FIGS. 19 to 21), the pad oxide layer 20 (FIGS. 19 to 21) and the sacrificial layer 11 (FIGS. 19 to 21) are etched.

Referring to FIGS. 2 to 7, a gate contact CB which penetrates the first capping pattern 131 in the vertical direction DR3 and is connected to the first gate electrode G1 may be formed. Also, a source/drain contact CA which penetrates the first interlayer insulating layer 160 in the vertical direction DR3 and is connected to the source/drain regions SD may be formed. A silicide layer SL may be formed between the source/drain region SD and the source/drain contact CA.

In an embodiment, the etching stop layer 170 and the second interlayer insulating layer 180 may then be sequentially formed on the first interlayer insulating layer 160, the first and second capping patterns 131 and 132, the gate contact CB, and the source/drain contact CA. The first via V1 which penetrates the second interlayer insulating layer 180 and the etching stop layer 170 in the vertical direction DR3 and is connected to the source/drain contact CA may then be formed. In addition, the second via V2 which penetrates the second interlayer insulating layer 180 and the etching stop layer 170 in the vertical direction DR3 and is connected to the gate contact CB may be formed. The semiconductor device shown in FIGS. 2 to 7 may be fabricated through such a fabricating process.

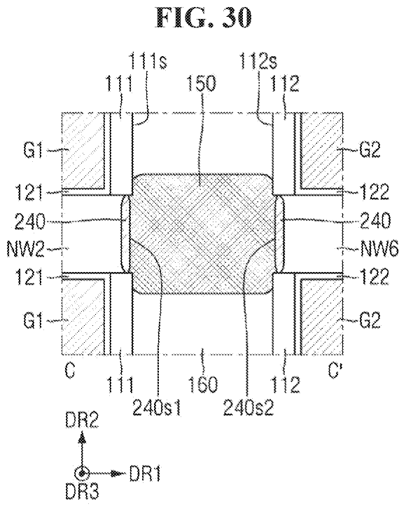

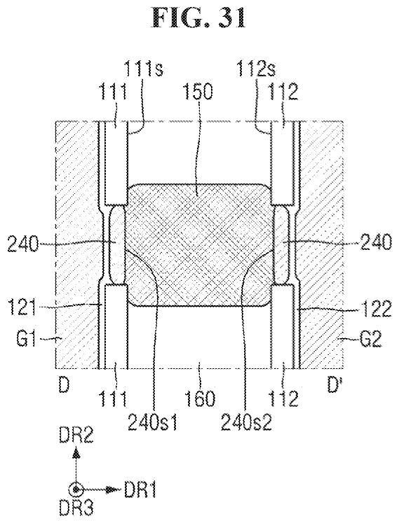

Hereinafter, a semiconductor device according to some embodiments of the present disclosure will be described with reference to FIGS. 30 and 31. The description will focus on differences from the semiconductor device shown in FIGS. 1 to 7 and a repeated description of similar or identical elements may be omitted for economy of description.

FIGS. 30 and 31 are plan views for explaining the semiconductor device according to some other embodiments of the present disclosure.

Referring to FIGS. 30 and 31, in the semiconductor device according to some embodiments of the present disclosure, the side walls 240s1 and 240s2 of the first layer 240 in direct contact with the second layer 150 may be formed to be partially recessed beyond each of the side wall 111s of the first gate spacer 111 and the side wall 112s of the second gate spacer 112.

As shown in FIG. 30, for example, on the side walls of the second nanosheet NW2, the side wall 111s of the first gate spacer 111 in direct contact with the second layer 150 may protrude further towards the second layer 150 (e.g., in the first direction DR1) beyond the first side wall 240s1 of the first layer 240 in direct contact with the second layer 150. Also, for example, on the side walls of the sixth nanosheet NW6, the side wall 112s of the second gate spacer 112 in direct contact with the second layer 150 may protrude further towards the second layer 150 (e.g., in a direction opposite to the first direction DR1) beyond the second side wall 240s2 of the first layer 240 in direct contact with the second layer 150.

As shown in FIG. 31, for example, on the side wall of the first gate electrode G1 in direct contact with the second nanosheet NW2 (e.g., overlapping the side wall of the first gate electrode G1 in the first horizontal direction DR1), the side wall 111s of the first gate spacer 111 in direct contact with the second layer 150 may protrude further towards the second layer 150 (e.g., in the first direction DR1) beyond the first side wall 240s1 of the first layer 240 in direct contact with the second layer 150. Further, for example, on the side wall of the second gate electrode G2 in contact with the sixth nanosheet NW6 (e.g., overlapping the side wall of the second gate electrode G2 in the first horizontal direction DR1), the side wall 112s of the second gate spacer 112 in direct contact with the second layer 150 may protrude further towards the second layer 150 (e.g., in the direction opposite to the first direction DR1) beyond the second side wall 240s2 of the first layer 240 in direct contact with the second layer 150.

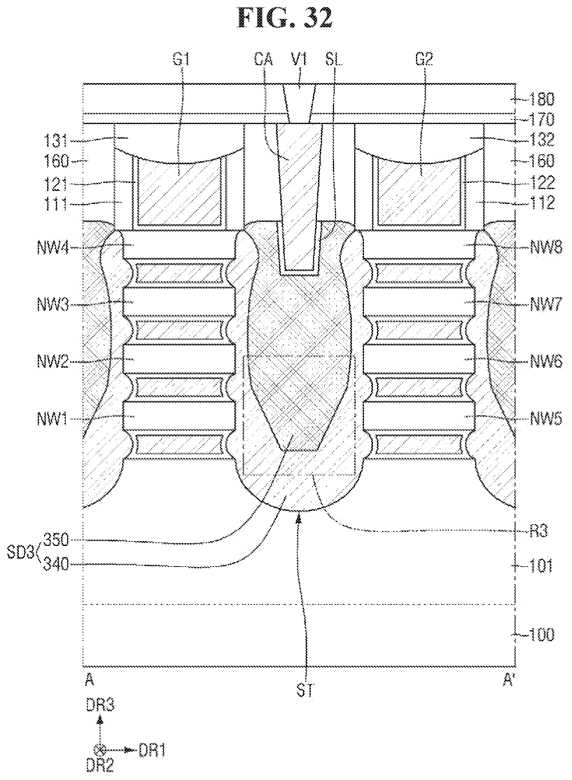

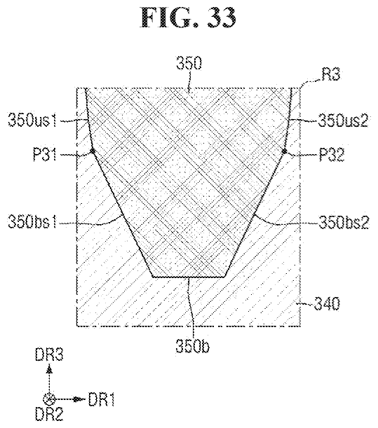

Hereinafter, a semiconductor device according to embodiments of the present disclosure will be described with reference to FIGS. 32 and 33. The description will focus on differences from the semiconductor device shown in FIGS. 1 to 7 and a repeated description of similar or identical elements may be omitted for economy of description.

FIG. 32 is a cross-sectional view for explaining a semiconductor device according to embodiments of the present disclosure. FIG. 33 is an enlarged view of a region R3 of FIG. 32.

Referring to FIGS. 32 and 33, in the semiconductor device according to embodiments of the present disclosure, the first connecting position P31 may be formed at a level in the vertical direction DR3 between the vertical levels of the upper surface of the first nanosheet NW1 and the lower surface of the second nanosheet NW2, and the second connecting position P32 may be formed at a level in the vertical direction DR3 between the vertical levels of the upper surface of the fifth nanosheet NW5 and the lower surface of the sixth nanosheet NW6.

For example, a source/drain region SD3 may include a first layer 340, and a second layer 350 that fills the source/drain trench ST on the first layer 340. In a cross-section taken along the first horizontal direction DR1, the second layer 350 may include a first lower side wall 350bs1, a second lower side wall 350bs2, a first upper side wall 350us1, a second upper side wall 350us2, and a lower surface 350b.

The first lower side wall 350bs1 of the second layer 350 may be a surface that faces the side wall of the first nanosheet NW1. The second lower side wall 350bs2 of the second layer 350 may be a surface that faces the side wall of the fifth nanosheet NW5. The second lower side wall 350bs2 of the second layer 350 may be opposite to the first lower side wall 350bs1 of the second layer 350 in the first horizontal direction DR1.

The first upper side wall 350us1 of the second layer 350 may be a surface that faces the side wall of the second nanosheet NW2. The second upper side wall 350us2 of the second layer 350 may be a surface that faces the side wall of the sixth nanosheet NW6. The second upper side wall 350us2 of the second layer 350 may be opposite to the first upper side wall 350us1 of the second layer 350 in the first horizontal direction DR1.

For example, in an embodiment in a cross-section taken along the first horizontal direction DR1, the first upper side wall 350us1 of the second layer 350 may be shown as a curved line. The first upper side wall 350us1 of the second layer 350 may be directly connected to the first lower side wall 350bs1 of the second layer 350. A position at which the first upper side wall 350us1 of the second layer 350 and the first lower side wall 350bs1 of the second layer 350 are directly connected to each other may be defined as a first connecting position P31. For example, the first connecting position P31 may be formed a level in the vertical direction DR3 between the vertical levels of the upper surface of the first nanosheet NW1 and the lower surface of the second nanosheet NW2.

For example, in an embodiment in a cross-section taken along the first horizontal direction DR1, the second upper side wall 350us2 of the second layer 350 may be shown as a curved line. The second upper side wall 350us2 of the second layer 350 may be directly connected to the second lower side wall 350bs2 of the second layer 350. A position at which the second upper side wall 350us2 of the second layer 350 and the second lower side wall 350bs2 of the second layer 350 are directly connected to each other may be defined as a second connecting position P32. For example, the second connecting position P32 may be formed at a level in the vertical direction DR3 between the vertical levels of the upper surface of the fifth nanosheet NW5 and the lower surface of the sixth nanosheet NW6.

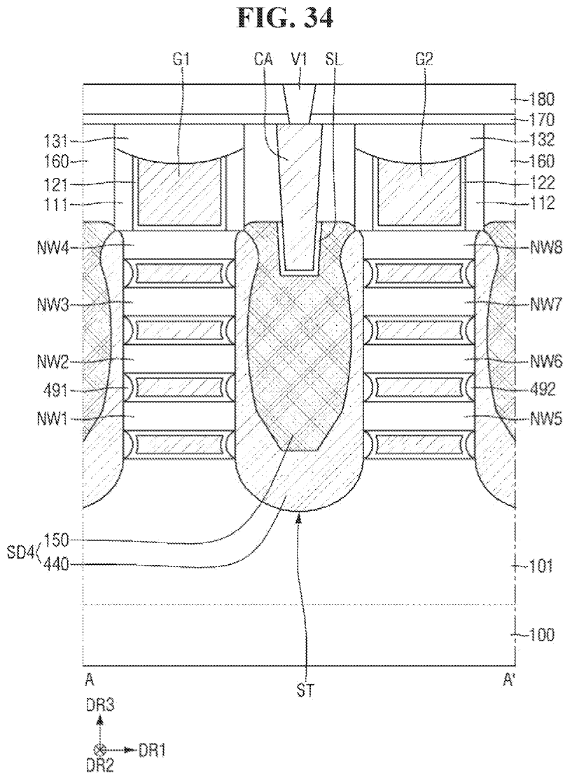

Hereinafter, a semiconductor device according to some embodiments of the present disclosure will be described with reference to FIG. 34. The description will focus on differences from the semiconductor device shown in FIGS. 1 to 7 and a repeated description of similar or identical elements may be omitted for economy of description.

FIG. 34 is a cross-sectional view for explaining a semiconductor device according embodiments of the present disclosure.

Referring to FIG. 34, in the semiconductor device according to some embodiments of the present disclosure, a first inner spacer 491 is disposed on the side wall of the first gate electrode G1 in the first horizontal direction DR1, and a second inner spacer 492 may be disposed on the side wall of the second gate electrode G2 in the first horizontal direction DR1.

For example, the source/drain region SD4 may include a first layer 440, and a second layer 150 that fills the source/drain trench ST on the first layer 440. The first inner spacer 491 may be disposed between the first gate insulating layer 121 and the first layer 440. The first inner spacer 491 may be in direct contact with each of the first gate insulating layer 121 and the first layer 440. The second inner spacer 492 may be disposed between the second gate insulating layer 122 and the first layer 440. The second inner spacer 492 may be in direct contact with each of the second gate insulating layer 122 and the first layer 440.

In an embodiment, each of the first inner spacer 491 and the second inner spacer 492 may include, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. However, embodiments of the present disclosure are not necessarily limited thereto.

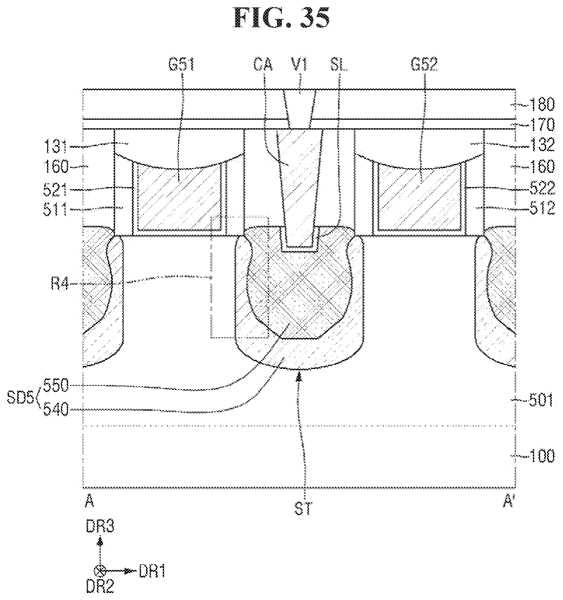

Hereinafter, a semiconductor device according to some embodiments of the present disclosure will be described with reference to FIGS. 35 to 37. The description will focus on differences from the semiconductor device shown in FIGS. 1 to 7 and a repeated description of similar or identical elements may be omitted for economy of description.

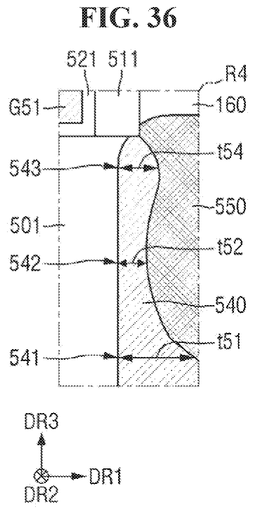

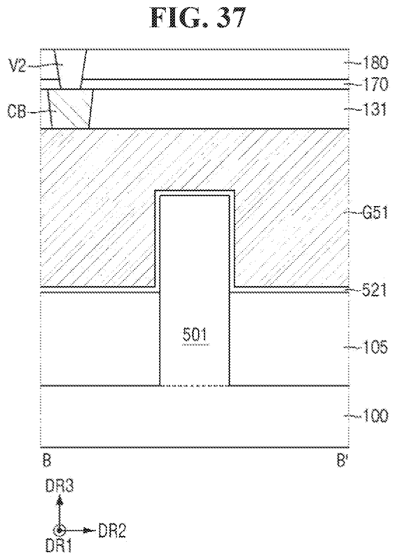

FIGS. 35 and 37 are cross-sectional views for explaining a semiconductor device according to some embodiments of the present disclosure. FIG. 36 is an enlarged view of a region R4 of FIG. 35.

Referring to FIGS. 35 to 37, the semiconductor device according to some embodiments of the present disclosure may include a fin-type transistor (FinFET). For example, the semiconductor device according to an embodiment of the present disclosure may include a substrate 100, an active pattern 501, a field insulating layer 105, first and second gate electrodes G51 and G52, first and second gate spacers 511 and 512, first and second gate insulating layers 521 and 522, first and second capping patterns 131 and 132, a source/drain region SD5, a first interlayer insulating layer 160, a source/drain contact CA, a silicide layer SL, a gate contact CB, an etching stop layer 170, a second interlayer insulating layer 180, and first and second vias V1 and V2. Hereinafter, the configurations explained in FIGS. 1 to 7 may be omitted

The active pattern 501 may extend on the substrate 100 in the first horizontal direction DR1. The first gate electrode G51 may extend on the active pattern 501 in the second horizontal direction DR2. The second gate electrode G52 may extend on the active pattern 501 in the second horizontal direction DR2. The second gate electrode G52 may be spaced apart from the first gate electrode G51 in the first horizontal direction DR1. The first gate spacer 511 may extend along both side walls of the first gate electrode G51 in the second horizontal direction DR2 on (e.g., directly thereon) the active pattern 501 and the field insulating layer 105. The second gate spacer 512 may extend along both side walls of the second gate electrode G52 in the second horizontal direction DR2 on (e.g., directly thereon) the active pattern 501 and the field insulating layer 105.

The first gate insulating layer 521 may be disposed between the first gate electrode G51 and the first gate spacer 511. The first gate insulating layer 521 may be disposed between the first gate electrode G51 and the active pattern 501. The first gate insulating layer 521 may be disposed between the first gate electrode G51 and the field insulating layer 105. The second gate insulating layer 522 may be disposed between the second gate electrode G52 and the second gate spacer 512. The second gate insulating layer 522 may be disposed between the second gate electrode G52 and the active pattern 501. The second gate insulating layer 522 may be disposed between the second gate electrode G52 and the field insulating layer 105.

The source/drain region SD5 may be disposed inside the source/drain trench ST. For example, the source/drain region SD5 may be disposed on both sides of each of the first gate electrode G51 and the second gate electrode G52. For example, the source/drain region SD5 may be disposed between the first gate electrode G51 and the second gate electrode G52. The source/drain region SD5 may include a first layer 540, and a second layer 550 disposed on (e.g., disposed directly thereon) the first layer 540.

The first layer 540 may be disposed along side walls and bottom surface of the source/drain trench ST. The first layer 540 may be in direct contact with each of the active pattern 501, the first gate spacer 511 and the second gate spacer 512. For example, the active pattern 501 may include a first portion 541 that overlaps the lower portion of the second layer 550 in the first horizontal direction DR1, a third portion 543 that overlaps the upper portion of the second layer 550 in the first horizontal direction DR1, and a second portion 542 disposed between the first portion 541 and the third portion 543.

For example, a thickness t54 in the first horizontal direction DR1 of the first layer 540 disposed on (e.g., overlapping in the first horizontal direction DR1) the side walls of the third portion 543 of the active pattern 501 may be greater than a thickness t52 in the first horizontal direction DR1 of the first layer $40 disposed on (e.g., overlapping in the first horizontal direction DR1) the side walls of the second portion 542 of the active pattern 501. For example, a thickness t51 in the first horizontal direction DR1 of the first layer 540 disposed on the side walls of the first portion 541 of the active pattern 501 may be greater than the thickness t52 in the first horizontal direction DR1 of the first layer 540 disposed on the side walls of the second portion 542 of the active pattern 501. Also, the thickness t51 in the first horizontal direction DR1 of the first layer 540 disposed on the side walls of the first portion 541 of the active pattern 501 may be greater than the thickness t54 in the first horizontal direction DR1 of the first layer 540 disposed on the side walls of the third portion 543 of the active pattern 501. For example, a slope profile of the lower surface of the second layer 550 may be similar to a slope profile of the lower surface of the second layer 150 of an embodiment shown in FIG. 4.

Although embodiments according to the present disclosure have been described above with reference to the accompanying drawings, the present disclosure is not limited to the described embodiments. Those skilled in the art will appreciate that the present disclosure may be embodied in other specific forms without changing the technical idea or essential features of the present disclosure. Accordingly, the above-described embodiments should be understood in all respects as illustrative and not restrictive.

What is claimed is:

1. A semiconductor device comprising:
a substrate;
an active pattern extending in a first horizontal direction on the substrate;
first to third nanosheets sequentially spaced apart from each other and stacked in a vertical direction on the active pattern;
a gate electrode extending in a second horizontal direction crossing the first horizontal direction on the active pattern, the gate electrode surrounding each of the first to third nanosheets;
a source/drain trench positioned on at least one side of the gate electrode on the active pattern; and
a source/drain region including a first layer disposed along side walls and a bottom surface of the source/drain trench, and a second layer disposed on the first layer, the second layer filling an inside of the source/drain trench,
wherein, in a cross-section taken along the first horizontal direction, the second layer includes a first lower side wall facing a side wall of the first nanosheet, a second lower side wall opposite to the first lower side wall in the first horizontal direction, and a lower surface connecting the first lower side wall and the second lower side wall to each other, the lower surface extending in the first horizontal direction, and
wherein, in a cross-section taken along the first horizontal direction, the first lower side wall of the second layer and the second lower side wall of the second layer extend to have a constant slope in opposite directions to each other.

2. The semiconductor device of claim 1,
wherein a thickness in the first horizontal direction of a portion of the first layer overlapping a side wall of the third nanosheet in the first horizontal direction is greater than a thickness in the first horizontal direction of a portion of the first layer overlapping a side wall of the second nanosheet in the first horizontal direction.

3. The semiconductor device of claim 2,
wherein a thickness in the first horizontal direction of a portion of the first layer overlapping the side wall of the first nanosheet in the first horizontal direction is greater than the thickness in the first horizontal direction of the portion of the first layer overlapping the side wall of the third nanosheet in the first horizontal direction.

4. The semiconductor device of claim 1,
wherein a width in the first horizontal direction of a portion of the second layer overlapping a side wall of the third nanosheet in the first horizontal direction is less than a width in the first horizontal direction of a portion of the second layer overlapping a side wall of the second nanosheet in the first horizontal direction.

5. The semiconductor device of claim 4,
wherein a width in the first horizontal direction of a portion of the second layer overlapping the side wall of the first nanosheet in the first horizontal direction is less than the width in the first horizontal direction of the portion of the second layer overlapping the side wall of the third nanosheet in the first horizontal direction.

6. The semiconductor device of claim 1, further comprising:
a gate spacer in direct contact with at least a portion of an upper surface of the third nanosheet, the gate spacer extending in the second horizontal direction on both side walls of the gate electrode spaced apart from each other in the first horizontal direction.

7. The semiconductor device of claim 1, further comprising:
a gate spacer in direct contact with at least a portion of an upper surface of the third nanosheet, the gate spacer extending in the second horizontal direction on both side walls of the gate electrode spaced apart from each other in the first horizontal direction,
wherein, a side wall of the first layer overlapping a side wall of the second nanosheet in the first horizontal direction and in direct contact with the second layer protrudes further towards the second layer beyond a side wall of the gate spacer in direct contact with the second layer.

8. The semiconductor device of claim 1, further comprising:
a gate spacer in direct contact with at least a portion of an upper surface of the third nanosheet, the gate spacer extending in the second horizontal direction on both side walls of the gate electrode spaced apart from each other in the first horizontal direction,
wherein, on a side wall of the second nanosheet, a side wall of the gate spacer in direct contact with the second layer further protrudes towards the second layer beyond a side wall of the first layer in direct contact with the second layer.

9. The semiconductor device of claim 1,
wherein, in the cross-section taken along the first horizontal direction, the second layer further comprises a first upper side wall facing a side wall of the second nanosheet, and a second upper side wall opposite to the first upper side wall in the first horizontal direction, and
wherein each of a first connecting position where the first upper side wall of the second layer and the first lower side wall of the second layer are directly connected to each other, and a second connecting position where the second upper side wall of the second layer and the second lower side wall of the second layer are directly connected to each other overlaps the first nanosheet in the first horizontal direction.

10. The semiconductor device of claim 1,
wherein, in the cross-section taken along the first horizontal direction, the second layer further comprises a first upper side wall facing a side wall of the second nanosheet, and a second upper side wall opposite to the first upper side wall in the first horizontal direction, and
wherein each of a first connecting position where the first upper side wall of the second layer and the first lower side wall of the second layer are directly connected to each other, and a second connecting position where the second upper side wall of the second layer and the second lower side wall of the second layer are directly connected to each other is positioned at a level in the vertical direction between levels in the vertical direction of an upper surface of the first nanosheet and a lower surface of the second nanosheet.

11. The semiconductor device of claim 1, further comprising:
a gate insulating layer disposed between the gate electrode and the first layer; and
an inner spacer disposed between the gate insulating layer and the first layer.

12. A semiconductor device comprising:
a substrate;
an active pattern extending in a first horizontal direction on the substrate;
first to third nanosheets sequentially spaced apart from each other and stacked in a vertical direction on the active pattern;
a gate electrode extending in a second horizontal direction crossing the first horizontal direction on the active pattern, the gate electrode surrounding each of the first to third nanosheets;
a gate spacer in direct contact with at least a portion of an upper surface of the third nanosheet, the gate spacer extending in the second horizontal direction on both side walls of the gate electrode spaced apart from each other in the first horizontal direction;
a source/drain trench positioned on at least one side of the gate electrode on the active pattern; and
a source/drain region including a first layer disposed along side walls and a bottom surface of the source/drain trench, and a second layer disposed on the first layer, the second layer filling the source/drain trench,
wherein a thickness in the first horizontal direction of a portion of the first layer overlapping a side wall of the third nanosheet in the first horizontal direction is greater than a thickness in the first horizontal direction of a portion of the first layer overlapping a side wall of the second nanosheet in the first horizontal direction, and
wherein a thickness in the first horizontal direction of a portion of the first layer overlapping a side wall of the first nanosheet in the first horizontal direction is greater than the thickness in the first horizontal direction of the portion of the first layer overlapping the side wall of the third nanosheet in the first horizontal direction.

13. The semiconductor device of claim 12,
wherein, in a cross-section taken along the first horizontal direction, the second layer comprises a first lower side wall facing the side wall of the first nanosheet, a second lower side wall opposite to the first lower side wall in the first horizontal direction, and a lower surface connecting the first lower side wall and the second lower side wall to each other, the lower surface extending in the first horizontal direction, and
wherein, in the cross-section taken along the first horizontal direction, each of the first lower side wall of the second layer and the second lower side wall of the second layer extends to have a constant slope in opposite directions to each other.

14. The semiconductor device of claim 12,
wherein a width in the first horizontal direction of a portion of the second layer overlapping the side wall of the third nanosheet in the first horizontal direction is less than a width in the first horizontal direction of a portion the second layer overlapping the side wall of the second nanosheet in the first horizontal direction.

15. The semiconductor device of claim 14,
wherein a width in the first horizontal direction of a portion of the second layer overlapping the side wall of the first nanosheet in the first horizontal direction is less than the width in the first horizontal direction of the portion of the second layer overlapping the side wall of the third nanosheet in the first horizontal direction.

16. The semiconductor device of claim 12,
wherein, a side wall of the first layer overlapping the side wall of the second nanosheet in the first horizontal direction and in direct contact with the second layer protrudes further towards the second layer beyond a side wall of the gate spacer in direct contact with the second layer.

17. The semiconductor device of claim 12,
wherein, in a cross-section taken along the first horizontal direction, the second layer comprises a first lower side wall facing the side wall of the first nanosheet, a second lower side wall opposite to the first lower side wall in the first horizontal direction, and a lower surface connecting the first lower side wall and the second lower side wall to each other, the lower surface extending in the first horizontal direction,
wherein, in the cross-section taken along the first horizontal direction, the second layer further comprises a first upper side wall facing the side wall of the second nanosheet, and a second upper side wall opposite to the first upper side wall in the first horizontal direction, and
wherein each of a first connecting position where the first upper side wall of the second layer and the first lower side wall of the second layer are directly connected to each other, and a second connecting position where the second upper side wall of the second layer and the second lower side wall of the second layer are directly connected to each other overlaps the first nanosheet in the first horizontal direction.

18. A semiconductor device comprising:
a substrate;
an active pattern extending in a first horizontal direction on the substrate;
first to third nanosheets sequentially spaced apart from each other and stacked in a vertical direction on the active pattern;
fourth to sixth nanosheets sequentially spaced apart from each other and stacked in the vertical direction on the active pattern, the fourth to sixth nanosheets are spaced apart from each of the first to third nanosheets in the first horizontal direction, the fourth to sixth nanosheets are disposed at a same vertical level as the first to third nanosheets, respectively;
a first gate electrode extending in a second horizontal direction crossing the first horizontal direction on the active pattern, the first gate electrode surrounding each of the first to third nanosheets;
a second gate electrode extending in the second horizontal direction on the active pattern, the second gate electrode is spaced apart from the first gate electrode in the first horizontal direction, the second gate electrode surrounding each of the fourth through sixth nanosheets;
a first gate spacer in direct contact with at least a portion of an upper surface of the third nanosheet, the first gate spacer extending in the second horizontal direction on both side walls of the first gate electrode spaced apart from each other in the first horizontal direction;
a second gate spacer in direct contact with at least a portion of an upper surface of the sixth nanosheet, the second gate spacer extending in the second horizontal direction on both side walls of the second gate electrode spaced apart from each other in the first horizontal direction;
a source/drain trench positioned between the first gate electrode and the second gate electrode on the active pattern; and
a source/drain region including a first layer disposed along side walls and a bottom surface of the source/drain trench, and a second layer disposed on the first layer, the second layer filling the source/drain trench,
wherein, in a cross-section taken along the first horizontal direction, the second layer includes a first lower side wall facing a side wall of the first nanosheet, a second lower side wall facing a side wall of the fourth nanosheet, and a lower surface connecting the first lower side wall and the second lower side wall to each other, the lower surface extending in the first horizontal direction,
wherein, in a cross-section taken along the first horizontal direction, each of the first lower side wall of the second layer and the second lower side wall of the second layer extends to have a constant slope in opposite directions to each other,
wherein a width in the first horizontal direction of a portion of the second layer overlapping the third nanosheet and the sixth nanosheet in the first horizontal direction is less than a width in the first horizontal direction of a portion of the second layer overlapping the second nanosheet and the fifth nanosheet in the first horizontal direction, and
wherein a width in the first horizontal direction of a portion of the second layer overlapping the first nanosheet and the fourth nanosheet in the first horizontal direction is less than the width in the first horizontal direction of the portion of the second layer overlapping the third nanosheet and the sixth nanosheet in the first horizontal direction.

19. The semiconductor device of claim 18,
wherein a thickness in the first horizontal direction of a portion of the first layer overlapping a side wall of the third nanosheet in the first horizontal direction is greater than a thickness in the first horizontal direction of a portion of the first layer overlapping a side wall of the second nanosheet in the first horizontal direction, and
wherein a thickness in the first horizontal direction of a portion of the first layer overlapping the side wall of the first nanosheet in the first horizontal direction is greater than the thickness in the first horizontal direction of the first layer disposed on the side wall of the third nanosheet.

20. The semiconductor device of claim 18, further comprising:
a first gate insulating layer disposed between the first gate electrode and the first layer;
a second gate insulating layer disposed between the second gate electrode and the first layer;
a first inner spacer disposed between the first gate insulating layer and the first layer; and
a second inner spacer disposed between the second gate insulating layer and the first layer.
